(19) United States
(12) Patent Application Publication
(10) Pub. No.: US 2012/0138913 A1
(43) Pub. Date: Jun. 7, 2012

(54) Electrically conductive nanostructures, method for making such nanostructures, electrically conductive polumer films containing such nanostructures, and electronic devices containing such films

(75) Inventors: Ahmed Alsayed, Cherry Hill, NJ (US); Lawrence Hough, Philadelphia, PA (US); Chantal Badre, Guttenberg, NJ (US)

(73) Assignee: RHODIA OPERATIONS, Aubervillers (FR)

(21) Appl. No.: 13/373,982

(22) Filed: Dec. 7, 2011

Related U.S. Application Data
(60) Provisional application No. 61/459,176, filed on Dec. 7, 2010.

(51) Int. Cl. H01L 51/30; H01B 1/12; C22C 5/06; H01B 1/22; B22F 9/18; B82Y 40/00; B82Y 99/00

(52) U.S. Cl. 257/40; 252/514; 252/510; 252/500; 75/370; 420/501; 977/762; 977/890; 257/E51.025; 977/932; 977/896

(57) ABSTRACT

A polymer film that contains a mixture of (i) an electrically conductive polymer, and (ii) anisotropic electrically conductive nanostructures, is disclosed, as well as a polymer composition that contains (a) a liquid carrier, (b) an electrically conductive polymer dissolved or dispersed in the liquid carrier, and (c) anisotropic electrically conductive nanostructures dispersed in the liquid carrier, and a method for making polymer film, that includes the steps of: (1) forming a layer of a polymer composition that contains (a) a liquid carrier, (b) one or more electrically conductive polymers dissolved or dispersed in the liquid carrier, and (c) anisotropic electrically conductive nanostructures dispersed in the liquid carrier, and (2) removing the liquid carrier from the layer.

### FIELD OF THE INVENTION

The present invention relates to electrically conductive nanostructures, a method for making such nanostructures, electrically conductive polymer films containing such nanostructures, and electronic devices containing such films.

### BACKGROUND

Transparent conductors, such as Indium Tin Oxide (ITO), combine the electrical conductivity of metal with the optical transparency of glass and are useful as components in electronic devices, such as in display devices. Flexibility is likely to become a broader challenge for ITO, which does not seem well suited to the next generation of display, lighting, or photovoltaic devices. These concerns have motivated a search for replacements using conventional materials and nanomaterials. There is variety of technical approaches for developing ITO substitutes and there are four areas in which the alternative compete: price, electrical conductivity, optical transparency, and physical resiliency.

Electrically conductive polymers, such as polythiophene polymers, particularly a polymer blend of poly(3,4-ethylenedioxythiophene) and poly(styrene sulfonate) (“PEDOT-PSS”) have been investigated as possible alternatives to ITO. The electrical conductivity of electrically conductive polymers is typically lower than that of ITO, but can be enhanced through the use of conductive fillers and dopants.

Methods for making electrically conductive metal nanostructures are known. Ducamp-Sanguesa, et. al., Synthesis and Characterization of Fine and Monodisperse Silver Particles of Uniform Shape, Journal of Solid State Chemistry 100, 272-280 (1992) and U.S. Pat. No. 7,585,349, issued Sep. 8, 2009 to Younan Xia, et. al., each describe synthesis of silver nanowires by reduction of a silver compound in a glycol in the presence of an organic protective agent, such as polyvinylpyrrolidone.

Structures comprising a network of silver nanowires encapsulated in an electrically conductive polymer have been described. U.S. Patent Application Publication No. 2008/0259262 describes forming such structures by depositing a network of metal nanowires on a substrate and then forming a conductive polymeric film in situ, e.g., by electrochemical polymerization using the metal nanowire network as an electrode. U.S. Patent Application Publication No. 2009/0129004 describes forming such structures by filtration of a silver nanowire dispersion to form a silver nanowire network, heat treating the network, transfer printing the heat treated network, and encapsulating the transfer printed network with polymer.

The performance of such electrically conductive polymer/silver nanowire composite films is, in some cases, comparable to that of ITO but the processing required to obtain composite films that exhibit that level of performance is quite demanding, for example, the above described films require processing steps, such as thermal treatment and compression, in order to ensure that sufficient electrical connections are made among the electrically conductive nanowires of the composite film to provide a film having high conductivity and transparency. There is an ongoing unresolved interest in increasing the electrical conductivity and optical transparency of electrically conductive polymer films.

### SUMMARY OF THE INVENTION

In a first aspect, the present invention is directed to a dispersion, comprising a liquid medium and, based on 100 parts by weight (“pbw”) of the dispersion, from about 0.1 to about 5 parts by weigh of silver nanowires dispersed in the liquid medium, wherein the silver nanowires have an average diameter of less than or equal to 60 nm with an average aspect ratio of greater than 100 and the dispersion comprises, based on 100 parts by weigh of the silver nanowires, less than 1 part by weight of vinylpyrrolidone polymer.

In a second aspect, the present invention is directed to a method for making silver nanowires by reacting, under an inert atmosphere, at a temperature of from 170° C. to 185° C., and in the presence of particles of silver chloride or silver bromide and at least one organic protective agent:

(a) at least one polyol, and
(b) at least one silver compound that is capable of producing silver metal when reduced.

In a third aspect, the present invention is directed to a polymer film, comprising a mixture of:

(a) an electrically conductive polymer, and
(b) silver nanowires,
wherein the film comprises, based on 100 parts by weigh of the silver nanowires, less than 1 part by weight of vinylpyrrolidone polymer.

In a fourth aspect, the present invention is directed to a polymer film, comprising a mixture of:

(a) an electrically conductive polymer, and
(b) carbon nanofibers.

In a fifth aspect, the present invention is directed to a polymer composition, comprising:

(a) a liquid carrier,
(b) an electrically conductive polymer dissolved or dispersed in the liquid carrier, and
(c) anisotropic electrically conductive nanostructures dispersed in the liquid carrier.

In a sixth aspect, the present invention is directed to a method for making polymer film, comprising:

(1) forming a layer of a polymer composition, said polymer composition comprising
(a) a liquid carrier,
(b) one or more electrically conductive polymers dissolved or dispersed in the liquid carrier, and
(c) anisotropic electrically conductive nanostructures dispersed in the liquid carrier, and
   (2) removing the liquid carrier from the layer.

In a seventh aspect, the present invention is directed to an electronic device, comprising at least one polymer film according to the present invention.

The respective polymer films of the present invention and polymer film component of the electronic device of the present invention typically provide high electrical conductivity and high optical transmittance.

### BRIEF DESCRIPTION OF THE DRAWINGS

FIG. 1 shows a schematic diagram of an electronic device according to the present invention.

FIG. 2 shows the two electrode configuration used to measure the sheet resistance of the films of Examples 1 to 18 and Comparative Example C1 and the sample film shown in the Figure is the film of Example 13.

FIG. 3 shows Sheet resistance and transmittance of the electrically conductive polymer films of Examples 9 to 13 as a function of silver nanowire content.

FIG. 4 shows sheet resistance and transmittance for the electrically conductive polymer films of Examples 13 to 16 as a function of spin coating speed.

FIG. 5 shows the length distribution of a sample population of the silver nanowires of Example 19 as a plot of percentage of nanowires versus length.

### DETAILED DESCRIPTION OF THE INVENTION

As used herein, the following terms have the meanings ascribed below:

“acidic group” means a group capable of ionizing to donate a hydrogen ion,

“anode” means an electrode that is more efficient for injecting holes compared to than a given cathode,

“buffer layer” generically refers to electrically conductive or semiconductive materials or structures that have one or more functions in an electronic device, including but not limited to, planarization of an adjacent structure in the device, such as an underlying layer, charge transport and/or charge injection properties, scavenging of impurities such as oxygen or metal ions, and other aspects to facilitate or to improve the performance of the electronic device,

“cathode” means an electrode that is particularly efficient for injecting electrons or negative charge carriers,

“confinement layer” means a layer that discourages or prevents quenching reactions at layer interfaces,

“doped” as used herein in reference to an electrically conductive polymer means that the electrically conductive polymer has been combined with a polymeric counterion for the electrically conductive polymer, which polymeric counterion is referred to herein as “dopant”, and is typically a polymeric acid, which is referred to herein as a “polymeric acid dopant”,

“doped electrically conductive polymer” means a polymer blend comprising an electrically conductive polymer and a polymeric counterion for the electrically conductive polymer,

“electrically conductive polymer” means any polymer or polymer blend that is inherently or intrinsically, without the addition of electrically conductive fillers such as carbon black or conductive metal particles, capable of electrical conductivity, more typically to any polymer or oligomer that exhibits a bulk specific conductance of greater than or equal to 10⁻⁷ Siemens per centimeter (“S/cm”), unless otherwise indicated, a reference herein to an “electrically conductive polymer” include any optional polymeric acid dopant,

“electrically conductive” includes conductive and semi-conductive,

“electroactive” when used herein in reference to a material or structure, means that the material or structure exhibits electronic or electro-radiative properties, such as emitting radiation or exhibiting a change in concentration of electron-hole pairs when receiving radiation,

“electronic device” means a device that comprises one or more layers comprising one or more semiconductor materials and makes use of the controlled motion of electrons through the one or more layers,

“electron injection/transport”, as used herein in reference to a material or structure, means that such material or structure that promotes or facilitates migration of negative charges through such material or structure into another material or structure,

“high-boiling solvent” refers to an organic compound which is a liquid at room temperature and has a boiling point of greater than 100° C.,

“hole transport” when used herein when referring to a material or structure, means such material or structure facilitates migration of positive charges through the thickness of such material or structure with relative efficiency and small loss of charge,

“layer” as used herein in reference to an electronic device, means a coating covering a desired area of the device, wherein the area is not limited by size, that is, the area covered by the layer can, for example, be as large as an entire device, be as large as a specific functional area of the device, such as the actual visual display, or be as small as a single sub-pixel,

“polymer” includes homopolymers and copolymers,

“polymer blend” means a blend of two or more polymers, and

“polymer network” means a three dimensional structure of interconnected segments of one or more polymer molecules, in which the segments are of a single polymer molecule and are interconnected by covalent bonds (a “crosslinked polymer network”), in which the segments are of two or more polymer molecules and are interconnected by means other than covalent bonds, (such as physical entanglements, hydrogen bonds, or ionic bonds) or by both covalent bonds and by means other than covalent bonds (a “physical polymer network”).

As used herein, the terminology “(Cₓ-C_{y})” in reference to an organic group, wherein x and y are each integers, means that the group may contain from x carbon atoms to y carbon atoms per group.

As used herein, the term “alkyl” means a monovalent straight, branched or cyclic saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, octyl, hexadecyl, octadecyl, eicosyl, behenyl, tricontyl, and tertacontyl. As used herein, the term “cycloalkyl” means a saturated hydrocarbon radical, more typically a saturated (C₅-C₂₂) hydrocarbon radical, that includes one or more cyclic alkyl rings, which may optionally be substituted on one or more carbon atoms of the ring with one or two (C₁-C₆)alkyl groups per carbon atom, such as, for example, cyclopentyl, cycloheptyl, cyclooctyl. The term “heteroalkyl” means an alkyl group wherein one or more of the carbon atoms within the alkyl group has been replaced by a hetero atom, such as nitrogen, oxygen, sulfur. The term “alkylene” refers to a divalent alkyl group including, for example, methylene, and poly(methylene).

As used herein, the term “hydroxyalkyl” means an alkyl radical, more typically a (C₁-C₂₂)alkyl radical, that is substituted with one or more hydroxyl groups, including, for example, hydroxymethyl, hydroxyethyl, hydroxypropyl, and hydroxydecyl.

As used herein, the term “alkoxyalkyl” means an alkyl radical that is substituted with one or more alkoxy substituents, more typically a (C₁-C₂₂)alkyloxy-(C₁-C₆)alkyl radical, including, for example, methoxymethyl, and ethoxybutyl.

As used herein, the term “alkenyl” means an unsaturated straight or branched hydrocarbon radical, more typically an unsaturated straight, branched, (C₂-C₂₂) hydrocarbon radical, that contains one or more carbon-carbon double bonds, including, for example, ethenyl, n-propenyl, and iso-propenyl,

As used herein, the term “cycloalkenyl” means an unsaturated hydrocarbon radical, typically an unsaturated (C₅-C₂₂) hydrocarbon radical, that contains one or more cyclic alkenyl rings and which may optionally be substituted on one or more carbon atoms of the ring with one or two (C₁-C₆)alkyl groups per carbon atom, including, for example, cyclohexenyl and cycloheptenyl.

As used herein, the term “aryl” means a monovalent unsaturated hydrocarbon radical containing one or more six-membered carbon rings in which the unsaturation may be represented by three conjugated double bonds, which may be substituted one or more of carbons of the ring with hydroxy, alkyl, alkoxyl, alkenyl, halo, haloalkyl, monocyclic aryl, or amino, including, for example, phenyl, methylphenyl, methoxyphenyl, dimethylphenyl, trimethylphenyl, chlorophenyl, trichloromethylphenyl, triisobutyl phenyl, tristyrylphenyl, and aminophenyl.

As used herein, the term “aralkyl” means an alkyl group substituted with one or more aryl groups, more typically a (C₁-C₁₈)alkyl substituted with one or more (C₆-C₁₄)aryl substituents, including, for example, phenylmethyl, phenylethyl, and triphenylmethyl.

As used herein, the term “polycyclic heteroaromatic” refers to compounds having more than one aromatic ring, at least one of which includes at least one hetero atom in the ring, wherein adjacent rings may be linked to each other by one or more bonds or divalent bridging groups or may be fused together.

As used herein, the following terms refer to the corresponding substituent groups:

“amido” is —R¹—C(O)N(R⁶)R⁶,

“amidosulfonate” is —R¹—C(O)N(R⁴)R²—SO₃Z,

“benzyl” is —CH₂—C₆H₅,

“carboxylate” is —R¹—C(O)O—Z or —R¹—O—C(O)—Z,

“ether” is —R¹—(O—R³)ₚ—O—R³,

“ether carboxylate” is —R¹—O—R²—C(O)O—Z or —R¹—O—R²—O—C(O)—Z,

“ether sulfonate” is —R¹—O—R²—SO₃Z,

“ester sulfonate” is —R¹—O—C(O)R²—SO₃Z,

“sulfonimide” is —R¹—SO₂—NH—SO₂—R³, and

“urethane” is —R¹—O—C(O)—N(R⁴)₂,

wherein:

each R¹ is absent or alkylene,

each R² is alkylene,

each R³ is alkyl,

each R⁴ is H or an alkyl,

p is 0 or an integer from 1 to 20, and

each Z is H, alkali metal, alkaline earth metal, N(R³)₄ or R³, wherein any of the above groups may be non-substituted or substituted, and any group may have fluorine substituted for one or more hydrogens, including perfluorinated groups.

With respect to bulk material, the dimensions referred to herein are averaged dimensions obtained by sampling individual nanostructures contained in the bulk material wherein the length measurements are obtained using optical microscopy, and the diameter measurements are determined using atomic force microscopy. Using this process, a sample of at least 20 nanostructures are measured to determine the respective diameters of each of the nanostructures of the sample population, and, in the case of anisotropic nanostructures, a sample of at least 100 of the anisotropic nanostructures are measured to determine the respective lengths of each of the nanostructures of the sample population. An average diameter, average length, and average aspect ratio are then determined for the nanostructures examined as follows. Average diameters for bulk nanostructure materials are given as arithmetic averages of the measured nanostructure population. In the case of anisotropic nanostructures, such as nanowires, average lengths are given as weighted average lengths, as determined by multiplying the length of each nanostructure of the sample population, by its weight, Wᵢ, summing the resultant products, LᵢWᵢ, summing the weights, Wᵢ, and then dividing the sum of the LᵢWᵢs by the total weight, i.e., the sum of Wᵢs, of nanostructures of the sample population according to Equation (1):

ΣLᵢWᵢ/ΣWᵢ Eq. (1)

to derive the weighted average length of the nanowire population. Average aspect ratios of anisotropic nanostructures are determined by dividing the weighted average length of the nanowire population by the average diameter of the anisotropic nanostructure population.

In one embodiment of the respective polymer film of the present invention and polymer film component of the electronic device of the present invention, the electrically conductive polymer forms a continuous phase and the anisotropic electrically conductive nanostructures form a continuous network, wherein each anisotropic electrically conductive nanostructures of the network is in physical contact with one or more of the other anisotropic electrically conductive nanostructures of the network and wherein the continuous electrically conductive polymer phase and continuous anisotropic nanostructure network interpenetrate each other to form an interpenetrating polymer/anisotropic nanostructure network.

In one embodiment of the respective polymer film of the present invention and polymer film component of the electronic device of the present invention, the polymer network is a physical polymer network formed by non-crosslinked molecules of the electrically conductive polymer.

In one embodiment of the respective polymer film of the present invention and polymer film component of the electronic device of the present invention, the polymer network is a crosslinked polymer network.

In one embodiment, the polymer composition of the present invention is a polymer dispersion, wherein the liquid carrier component of the dispersion may be any liquid in which the electrically conductive polymer component of the composition is insoluble, but within which the electrically conductive polymer component of the composition is dispersible. In one embodiment, the liquid carrier of the polymer composition of the present invention is an aqueous medium that comprises water and, optionally, one or more water miscible organic liquids, and the electrically conductive polymer is dispersible in the aqueous medium. Suitable water miscible organic liquids include polar aprotic organic solvents, such as, for example (C₁-C₆)alkanols, such as methanol, ethanol, and propanol. In one embodiment, the liquid carrier comprises, based on 100 pbw of the liquid medium, from about 10 to 100 pbw, more typically from about 50 pbw to 100 pbw, and even more typically, from about 90 to 100 pbw, water and from 0 pbw to about 90 pbw, more typically from 0 pbw to about 50 pbw, and even more typically from 0 pbw to about 10 pbw of one or more water miscible organic liquids. In one embodiment, the liquid carrier consists essentially of water. In one embodiment, the liquid carrier consists of water.

In one embodiment, the polymer composition is a polymer solution, wherein the liquid carrier component of the composition may be any liquid in which the electrically conductive polymer component of the composition is soluble. In one embodiment, the liquid carrier is an non-aqueous liquid medium and the electrically conductive polymer is soluble in and is dissolved in the non-aqueous liquid medium. Suitable non-aqueous liquid media include organic liquids that have a boiling point of less than 120° C., more typically, less than or equal to about 100° C., selected, based on the choice of electrically conductive polymer, from non-polar organic solvents, such as hexanes, cyclohexane, benzene, toluene, chloroform, and diethyl ether, polar aprotic organic solvents, such as dichloromethane, ethyl acetate, acetone, and tetrahydrofuran, polar protic organic solvents, such as methanol, ethanol, and propanol, as well as mixtures of such solvents.

In one embodiment, the liquid carrier may optionally further comprise, based on 100 pbw of the polymer composition of the present invention, from greater than 0 pbw to about 15 pbw, more typically from about 1 pbw to about 10 pbw, of an organic liquid selected from high boiling polar organic liquids, typically having a boiling point of at least 120° C., more typically from diethylene glycol, meso-erythritol, 1,2,3,4,-tetrahydroxybutane, 2-nitroethanol, glycerol, sorbitol, dimethyl sulfoxide, tetrahydrofurane, dimethyl formamide, and mixtures thereof.

The electrically conductive polymer component of the respective polymer composition, polymer film, and electronic device of the present invention may each comprise one or more homopolymers, one or more co-polymers of two or more respective monomers, or a mixture of one or more homopolymers and one or more copolymers. The respective dispersion, film and electrically conductive polymer film component of the electronic device of the present invention may each comprise a single conductive polymer or may comprise a blend two or more conductive polymers which differ from each other in some respect, for example, in respect to composition, structure, or molecular weight.

In one embodiment, the electrically conductive polymer of the dispersion, film and/or electrically conductive polymer film component of the electronic device of the present invention, comprises one or more electrically conductive polymers selected from electrically conductive polythiophene polymers, electrically conductive poly(selenophene) polymers, electrically conductive poly(telurophene) polymers, electrically conductive polypyrrole polymers, electrically conductive polyaniline polymers, electrically conductive fused polycylic heteroaromatic polymers, and blends of any such polymers.

In one embodiment, the electrically conductive polymer comprises one or more polymers selected from electrically conductive polythiophene polymers, electrically conductive poly(selenophene) polymers, electrically conductive poly(telurophene) polymers, and mixtures thereof. Suitable polythiophene polymers, poly(selenophene) polymers, poly(telurophene) polymers and methods for making such polymers are generally known. In one embodiment, the electrically conductive polymer comprises at least one electrically conductive polythiophene polymer, electrically conductive poly(selenophene) polymer, or electrically conductive poly(telurophene) polymer that comprises 2 or more, more typically 4 or more, monomeric units according to structure (I) per molecule of the polymer:

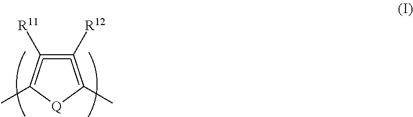

wherein:

Q is S, SE, or Te, and

each occurrence of R¹¹ and each occurrence of R¹² is independently H, alkyl, alkenyl, alkoxy, alkanoyl, alkylhio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxy, hydroxyalkyl, benzyl, carboxylate, ether, ether carboxylate, amidosulfonate, ether sulfonate, ester sulfonate, and urethane, or both the R¹ group and R² group of a given monomeric unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, selenium, telurium, sulfur, or oxygen atoms.

In one embodiment, Q is S, the R¹¹ and R¹² of the monomeric unit according to structure (I) are fused and the electrically conductive polymer comprises a polydioxythiopene polymer that comprises 2 or more, more typically 4 or more, monomeric units according to structure (I.a) per molecule of the polymer:

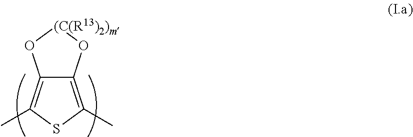

wherein:

each occurrence of R¹³ is independently H, alkyl, hydroxy, heteroalkyl, alkenyl, heteroalkenyl, hydroxalkyl, amidosulfonate, benzyl, carboxylate, ether, ether carboxylate, ether sulfonate, ester sulfonate, or urethane, and

m′ is 2 or 3.

In one embodiment, all R¹³ groups of the monomeric unit according to structure (I.a) are each H, alkyl, or alkenyl. In one embodiment, at least one R¹³ groups of the monomeric unit according to structure (I.a) is not H. In one embodiment, each R¹³ groups of the monomeric unit according to structure (I.a) is H.

In one embodiment, the electrically conductive polymer comprises an electrically conductive polythiophene homopolymer of monomeric units according to structure (I.a) wherein each R¹³ is H and m′ is 2, known as poly(3,4-ethylenedioxythiophene), more typically referred to as “PEDOT”.

In one embodiment, the electrically conductive polymer comprises one or more electrically conductive polypyrrole polymers. Suitable electrically conductive polypyrrole polymers and methods for making such polymers are generally known. In one embodiment, the electrically conductive polymer comprises a polypyrrole polymer that comprises 2 or more, more typically 4 or more, monomeric units according to structure (II) per molecule of the polymer:

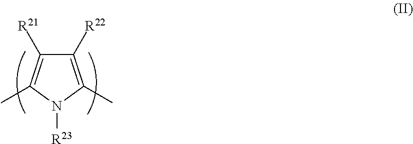

wherein:

each occurrence of R²¹ and each occurrence of R²² is independently H, alkyl, alkenyl, alkoxy, alkanoyl, alkylhio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxy, hydroxyalkyl, benzyl, carboxylate, ether, amidosulfonate, ether carboxylate, ether sulfonate, ester sulfonate, and urethane, or the R²¹ and R²² of a given pyrrole unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, sulfur or oxygen atoms, and

each occurrence of R²³ is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, hydroxy, hydroxyalkyl, benzyl, carboxylate, ether, ether carboxylate, ether sulfonate, ester sulfonate, and urethane

In one embodiment, each occurrence of R²¹ and each occurrence of R²² is independently H, alkyl, alkenyl, alkoxy, cycloalkyl, cycloalkenyl, hydroxy, hydroxyalkyl, benzyl, carboxylate, ether, amidosulfonate, ether carboxylate, ether sulfonate, ester sulfonate, urethane, epoxy, silane, siloxane, or alkyl, wherein the alky group may optionally be substituted with one or more of sulfonic acid, carboxylic acid, acrylic acid, phosphoric acid, phosphonic acid, halogen, nitro, cyano, hydroxyl, epoxy, silane, or siloxane moieties.

In one embodiment, each occurrence of R²³ is independently H, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one embodiment, each occurrence of R²¹, R²², and R²³ is H.

In one embodiment, R²¹ and R²² are fused to form, together with the carbon atoms to which they are attached, a 6- or 7-membered alicyclic ring, which is further substituted with a group selected from alkyl, heteroalkyl, hydroxy, hydroxyalkyl, benzyl, carboxylate, ether, ether carboxylate, ether sulfonate, ester sulfonate, and urethane. In one embodiment, and R²² are fused to form, together with the carbon atoms to which they are attached, a 6- or 7-membered alicyclic ring, which is further substituted with an alkyl group. In one embodiment, R²¹ and R²² are fused to form, together with the carbon atoms to which they are attached, a 6- or 7-membered alicyclic ring, which is further substituted with an alkyl group having at least 1 carbon atom.

In one embodiment, R²¹ and R²² are fused to form, together with the carbon atoms to which they are attached, a —O—(CHR²⁴)n′-O— group, wherein:

each occurrence of R²⁴ is independently H, alkyl, hydroxy, hydroxyalkyl, benzyl, carboxylate, amidosulfonate, ether, ether carboxylate, ether sulfonate, ester sulfonate, and urethane, and

n′ is 2 or 3.

In one embodiment, at least one R²⁴ group is not hydrogen. In one embodiment, at least one R²⁴ group is a substituent having F substituted for at least one hydrogen. In one embodiment, at least one Y group is perfluorinated.

In one embodiment, the electrically conductive polymer comprises one or more electrically conductive polyaniline polymers. Suitable electrically conductive polyaniline polymers and methods of making such polymers are generally known. In one embodiment, the electrically conductive polymer comprises a polyaniline polymer that comprises 2 or more, more typically 4 or more, monomeric units selected from monomeric units according to structure (III) and monomeric units according to structure (III.a) per molecule of the polymer:

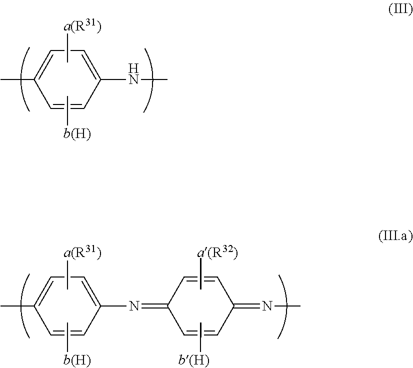

wherein:

each occurrence of R³¹ and R³²s independently alkyl, alkenyl, alkoxy, cycloalkyl, cycloalkenyl, alkanoyl, alkylhio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more of sulfonic acid, carboxylic acid, halo, nitro, cyano or epoxy moieties, or two R³¹ or R³² groups on the same ring may be fused to form, together with the carbon atoms to which they are attached, a 3, 4, 5, 6, or 7-membered aromatic or alicyclic ring, which ring may optionally include one or more divalent nitrogen, sulfur or oxygen atoms. and

each a and a′ is independently an integer from 0 to 4,

each b and b′ is integer of from 1 to 4, wherein, for each ring, the sum of the a and b coefficients of the ring or the a′ and b′ coefficients of the ring is 4.

In one embodiment, a or a′=0 and the polyaniline polymer is an non-substituted polyaniline polymers referred to herein as a “PANI” polymer.

In one embodiment, the electrically conductive polymer comprises one or more electrically conductive polycylic heteroaromatic polymers. Suitable electrically conductive polycylic heteroaromatic polymers and methods for making such polymers are generally known. In one embodiment, the electrically conductive polymer comprises one or more polycylic heteroaromatic polymers that comprise 2 or more, more typically 4 or more, monomeric units per molecule that are derived from one or more heteroaromatic monomers, each of which is independently according to Formula (IV):

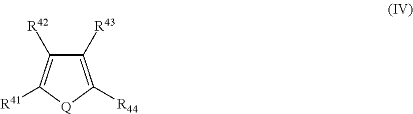

wherein:

Q is S or NH,

R⁴¹, R⁴², R⁴³, and R⁴⁴ are each independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxy, hydroxyalkyl, benzyl, carboxylate, ether, ether carboxylate, amidosulfonate, ether sulfonate, ester sulfonate, or urethane, provided that at least one pair of adjacent substituents R⁴¹ and R⁴², R⁴² and R⁴³, or R⁴³ and R⁴⁴ are fused to form, together with the carbon atoms to which they are attached, a 5 or 6-membered aromatic ring, which ring may optionally include one or more hetero atoms, more typically selected from divalent nitrogen, sulfur and oxygen atoms, as ring members.

In one embodiment, the polycylic heteroaromatic polymers comprise 2 or more, more typically 4 or more, monomeric units per molecule that are derived from one or more heteroaromatic monomers, each of which is independently according to structure (V):

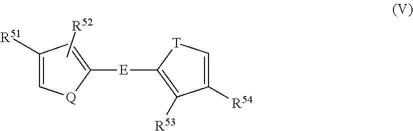

wherein:

Q is S, Se, Te, or NR⁵⁵,

T is S, Se, Te, NR⁵⁵, O, Si(R⁵⁵)₂, or PR⁵⁵,

E is alkenylene, arylene, and heteroarylene,

R⁵⁵ is hydrogen or alkyl,

R⁵¹, R⁵², R⁵³, and R⁵⁴ are each independently H, alkyl, alkenyl, alkoxy, alkanoyl, alkylhio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, hydroxy, hydroxyalkyl, benzyl, carboxylate, ether, ether carboxylate, amidosulfonate, ether sulfonate, and urethane, or where each pair of adjacent substituents R⁵¹ and R⁵² and adjacent substituents R⁵³ and R⁵⁴ may independently form, together with the carbon atoms to which they are attached, a 3, 4, 5, 6, or 7-membered aromatic or alicyclic ring, which ring may optionally include one or more hetero atoms, more typically selected from divalent nitrogen, sulfur and oxygen atoms, as ring members.

In one embodiment, the electrically conductive polymer comprises an electrically conductive copolymer that comprises at least one first monomeric unit per molecule that is according to formula (I), (I.a), (II), (III), or (III.a) or that is derived from a heteroaromatic monomer according to structure (IV) or (V) and further comprises one or more second monomeric units per molecule that differ in structure and/or composition from the first monomeric units. Any type of second monomeric units can be used, so long as it does not detrimentally affect the desired properties of the copolymer. In one embodiment, the copolymer comprises, based on the total number of monomer units of the copolymer, less than or equal to 50%, more typically less than or equal to 25%, even more typically less than or equal to 10% of second monomeric units.

Exemplary types of second monomeric units include, but are not limited to those derived from alkenyl, alkynyl, arylene, and heteroarylene monomers, such as, for example, fluorene, oxadiazole, thiadiazole, benzothiadiazole, phenylene vinylene, phenylene ethynylene, pyridine, diazines, and triazines, all of which may be further substituted, that are copolymerizable with the monomers from which the first monomeric units are derived.

In one embodiment, the electrically conductive copolymers are made by first forming an intermediate oligomer having the structure A-B-C, where A and C represent first monomeric units, which can be the same or different, and B represents a second monomeric unit. The A-B-C intermediate oligomer can be prepared using standard synthetic organic techniques, such as Yamamoto, Stille, Grignard metathesis, Suzuki and Negishi couplings. The electrically conductive copolymer is then formed by oxidative polymerization of the intermediate oligomer alone, or by copolymerization of the intermediate oligomer with one or more additional monomers.

In one embodiment, the electrically conductive polymer comprises an electrically conductive copolymer of two or more monomers. In one embodiment, the monomers comprise at least one monomer selected from a thiophene monomer, a pyrrole monomer, an aniline monomer, and a polycyclic aromatic monomer.

In one embodiment, the weight average molecular weight of the electrically conductive polymer is from about 1000 to about 2,000,000 grams per mole, more typically from about 5,000 to about 1,000,000 grams per mole, and even more typically from about 10,000 to about 500,000 grams per mole.

In one embodiment, the electrically conductive polymer of the respective polymer composition, polymer film, and electronic device of the present invention further comprises a polymeric acid dopant, typically (particularly where the liquid medium of the polymer composition is an aqueous medium), a water soluble polymeric acid dopant. In one embodiment, the electrically conductive polymers used in the new compositions and methods are prepared by oxidatively polymerizing the corresponding monomers in aqueous solution containing a water soluble acid, typically a water-soluble polymeric acid. In one embodiment, the acid is a polymeric sulfonic acid. Some non-limiting examples of the acids are poly(styrenesulfonic acid) (“PSSA”), poly(2-acrylamido-2-methyl-1-propanesulfonic acid) (“PAAMPSA”), and mixtures thereof. The acid anion provides the dopant for the conductive polymer. The oxidative polymerization is carried out using an oxidizing agent such as ammonium persulfate, sodium persulfate, and mixtures thereof. Thus, for example, when aniline is oxidatively polymerized in the presence of PMMPSA, the doped electrically conductive polymer blend PANI/PAAMPSA is formed. When ethylenedioxythiophene (EDT) is oxidatively polymerized in the presence of PSSA, the doped electrically conductive polymer blend PEDT/PSS is formed. The conjugated backbone of PEDT is partially oxidized and positively charged. Oxidatively polymerized pyrroles and thienothiophenes also have a positive charge which is balanced by the acid anion.

In one embodiment, the water soluble polymeric acid selected from the polysulphonic acids, more typically, poly(styrene sulfonic acid), or poly(acrylamido-2-methyl-1-propane-sulfonic acid), or a polycarboxylic acid, such as polyacrylic acid polymethacrylic acid, or polymaleic acid.

In one embodiment, the electrically conductive polymer component of the respective polymer film, polymer solution or dispersion, and/or electronic device of the present invention, comprises, based on 100 pbw of the electrically conductive polymer:
(i) from greater than 0 pbw to 100 pbw, more typically from about 10 to about 50 pbw, and even more typically from about 20 to about 50 pbw, of one or more electrically conductive polymers, more typically of one or more electrically conductive polymer comprising monomeric units according to structure (I.a), more typically one or more polythiophene polymers comprising monomeric units according to structure (I.a), wherein Q is S, and even more typically of one or more electrically conductive polymers comprising poly(3,4-ethylenedioxythiophene), and
(ii) from 0 pbw to 100 pbw, more typically from about 50 to about 90 pbw, and even more typically from about 50 to about 80 pbw, of one or more water soluble polymeric acid dopants, more typically of one or more water soluble polymeric acid dopants comprising a poly(styrene sulfonic acid) dopant.

As used herein, the term “nanostructures” generally refers to nano-sized structures, at least one dimension of which is less than or equal to 500 nm, more typically, less than or equal to 250 nm, or less than or equal to 100 nm, or less than or equal to 50 nm, or less than or equal to 25 nm.

The anisotropic electrically conductive nanostructures can be of any anisotropic shape or geometry. As used herein, the terminology “aspect ratio” in reference to a structure means the ratio of the structure's longest characteristic dimension to the structure's next longest characteristic dimension. As discussed above, the aspect ratios referred to herein in regard to bulk material are typically average aspect ratios fro the bulk material. In one embodiment, the anisotropic electrically conductive nanostructures have an elongated shape with a longest characteristic dimension, i.e., a length, and a next longest characteristic dimension, i.e., a width or diameter, with an aspect ratio of greater than 1. Typical anisotropic nanostructures include nanowires and nanotubes, as defined herein.

The electrically conductive nanostructures can be solid or hollow. Solid nanostructures include, for example, nanoparticles and nanowires. “Nanowires” refers to solid elongated nanostructures. Typically, the nanowires have an average aspect ratio of greater than 10, or greater than 50, or greater than 100, or greater than 200, or greater than 300, or greater than 400. Typically, the nanowires are greater than 500 nm, or greater than 1 μm, or greater than 10 μm, in length.

Hollow nanostructures include, for example, nanotubes. “Nanotubes” refer to hollow elongated nanostructures. Typically, the nanotubes have an average aspect ratio of greater than 10, or greater than 50, or greater than 100. Typically, the nanotubes are greater than 500 nm, or greater than 1 μm, or greater than 10 μm, in length.

The nanostructures can be formed of any electrically conductive material, such as for example, metallic materials or non-metallic materials, such as carbon or graphite, and may comprise a mixture of nanostructures formed form different electrically conductive materials, such as a mixture of carbon fibers and silver nanowires.

In one embodiment, the anisotropic electrically conductive nanostructures comprise anisotropic electrically conductive metallic nanostructures. The metallic material can be an elemental metal (e.g., transition metals) or a metal compound (e.g., metal oxide). The metallic material can also be a metal alloy or a bimetallic material, which comprises two or more types of metal. Suitable metals include, but are not limited to, silver, gold, copper, nickel, gold-plated silver, platinum and palladium. In one embodiment, the anisotropic electrically conductive nanostructures comprise silver nanowires.

In one embodiment, the anisotropic electrically conductive nanostructures comprise anisotropic electrically conductive non-metallic nanostructures, such as anisotropic carbon or graphite nanostructures. In one embodiment, the anisotropic electrically conductive nanostructures comprise carbon nanofibers.

In one embodiment, the anisotropic electrically conductive nanostructures comprise, based on 100 pbw of the anisotropic electrically conductive nanostructures, from greater than 0 to less than 100 pbw electrically conductive metallic nanostructures, more typically, silver nanowires, and from greater than 0 to less than 100 pbw electrically conductive non-metallic nanostructures, more typically, carbon nanofibers.

Metal nanowires and metal nanotubes are nanowires or nanotubes formed of metal, metal alloys, plated metals, or metal oxides. Suitable metal nanowires include, but are not limited to, silver nanowires, gold nanowires, copper nanowires, nickel nanowires, gold-plated silver nanowires, platinum nanowires, and palladium nanowires. Suitable metal nanotubes include gold nanotubes.

In one embodiment, the anisotropic electrically conductive nanostructures are elongated in shape and have a long dimension of from about 5 to about 150 μm and a transverse dimension, for example, a average diameter of from about 5 to about 400 nm.

In one embodiment, the anisotropic electrically conductive nanostructures comprise silver nanotubes. Suitable metal nanotubes have similar dimensions as those described below for metal nanowires, wherein, for nanotubes, the diameter refers to the outer diameter of the nanotubes. Suitable silver nanotubes may be made by known methods, such for example, those disclosed by U.S. Pat. No. 7,585,349 to Xia, et al.

In one embodiment, the anisotropic electrically conductive nanostructure component of the respective film, composition, method and device of the present invention comprises silver nanowires.

In one embodiment, the anisotropic electrically conductive structures comprise silver nanowires having an average diameter of from about 40 to about 400 nm, more typically from about 40 to about 150 nm, and an average length of from about 5 to about 150 μm, more typically from about 10 to about 100 μm. In one embodiment, the anisotropic electrically conductive structures comprise silver nanowires having an average diameter of from about 40 nm to 80 nm and an average length of from about 10 to about 100 μm. In one embodiment, the anisotropic electrically conductive structures comprise silver nanowires having an average of from greater than 80 nm to about 100 nm and an average length of from about 10 to about 80 μm. In one embodiment, the anisotropic electrically conductive structures comprise silver nanowires having an average diameter of from greater than 100 nm, more typically from about 200 nm, to about 400 nm and an average length of from about 10 to about 50 μm.

In one embodiment, the anisotropic electrically conductive structures comprise silver nanowires having an average diameter of from about from 5 nm to 200 nm, an average length of from about 10 to about 100 μm, and an average aspect ratio of greater than 100, or greater than 150, or greater than 200, or greater than 300, or greater than 400

Suitable silver nanowires may be made by known methods, such for example, by reduction of silver nitrate in ethylene glycol in the presence of an organic protective agent, such as polyvinylpyrrolidone, as disclosed by, for example, Ducamp-Sanguesa, et. al., Synthesis and Characterization of Fine and Monodisperse Silver Particles of Uniform Shape, Journal of Solid State Chemistry 100, 272-280 (1992) and U.S. Pat. No. 7,585,349, issued Sep. 8, 2009 to Younan Xia et. al. Silver nanowires are commercially available from, for example, Blue Nano Inc., 17325 Connor Quay Court, Cornelius, N.C. 28031, U.S.A.

In one embodiment, silver nanowires are made by reacting, in an inert atmosphere at a temperature of from 170° C. to 185° C., more typically from 170° C., or from 175° C., or from 178° C., to 184° C., to 183° C., or to 182° C., and in the presence of and in the presence of particles of silver chloride and/or particles of silver bromide and at least one organic protective agent:

(a) at least one polyol, and
(b) at least one silver compound that is capable of producing silver metal when reduced.

The at least one polyol serves as liquid medium in which to conduct the reaction and as a reducing agent that reduces the silver compound to silver metal.

The total amount of silver compound added to the reaction mixture is typically from about 15×10⁻³ to 150×10⁻³ moles of the silver compound per Liter of reaction mixture. The silver compound is typically fed to the reaction mixture as a dilute solution of the silver compound in the polyol comprising from about 10 g to 100 g of the silver compound per 1000 g polyol at a rate that is sufficiently slow as to avoid reducing the temperature of the reaction mixture.

The amount of organic protective agent is typically from 0.1 to 10, more typically 1 to 5 pbw, of the organic protective agent per 1 pbw of silver compound.

While not wishing to be bound by theory, it is believed that the particles of silver chloride and/or particles of silver bromide catalyze growth of the silver nanowires, but do not participate as a reactive “seeds” that become incorporated within the silver nanowires. In general, the wires are made in the presence of from about 5.4×10⁻⁵ moles to about 5.4×10⁻³ moles of particles of silver chloride and/or particles of silver bromide per Liter of reaction mixture. The concentration of silver chloride or silver bromide particles in the reaction mixture was found, other reaction parameters being equal, to influence the both the diameter and the length of the silver nanowire product, with a higher concentration of the particles tending to produce silver nanowires having a smaller average diameter and shorter average length. While the average diameter and average length of the nanowires was found to vary, the average aspect ratio of the nanowires remained substantially unchanged over a wide range of concentration of the silver chloride or silver bromide particles.

In one embodiment, colloidal particles of silver chloride and/or silver bromide are added to the reaction mixture. The colloidal particles may have a particle size of from 10 nm to 10 μm, more typically of from 50 nm to 10 μm.

In one embodiment, the particles of silver chloride or silver bromide are formed in the polyol a preliminary step, wherein a silver compound and polyol are reacted in the presence of a source of chloride or bromide ions, typically in with the silver compound in an excess of from greater than 1, more typically from about 1.01 to about 1.2 moles, of silver compound per mole chloride or bromide ions. In one embodiment, from about 0.54×10⁻⁴ to 5.4×10⁻⁴ moles silver compound per liter of reaction mixture are reacted in the presence of from about 0.54×10⁻⁴ to 5.4×10⁻⁴ moles of the source of chloride and/or bromide ions per liter of reaction mixture to form silver chloride and/or silver bromide seed particles in the reaction mixture. In one embodiment particles of silver chloride or silver bromide are formed at a temperature of from about 140° C. to 185° C., more typically from 160° C. to 185° C., more typically from 170° C., or from 175° C., or from 178° C., to 184° C., to 183° C., or to 182° C. The formation of the silver chloride or silver bromide particles is typically conducted over a time period of from about 1 minute to 10 minutes.

In one embodiment from about 15×10⁻³ to 150×10⁻³ moles of the silver compound per Liter of reaction mixture are added in a second reaction step. The growth step is conducted at a temperature of 170° C. to 185° C., more typically from 170° C., or from 175° C., or from 178° C., to 184° C., to 183° C., or to 182° C. The second reaction step of the reaction is typically conducted over a time period of from about 10 minutes to 4 hours, more typically from 30 minutes to 1 hour.

In one embodiment, the particles of silver chloride or silver bromide are formed in the polyol simultaneously with the formation of the silver nanowires in a single step, wherein a silver compound and polyol are reacted in the presence of a source of chloride or bromide ions, typically in with the silver compound in very large molar excess. The single step formation reaction is conducted at a temperature of from 170° C. to 185° C., more typically from 170° C., or from 175° C., or from 178° C., to 184° C., to 183° C., or to 182° C. The single step formation reaction is typically conducted over a time period of from about 10 minutes to 4 hours, more typically from 30 minutes to 1 hour.

In one embodiment, the reaction is conducted under an inert atmosphere, such as a nitrogen or argon atmosphere.

Suitable polyols are organic compounds having a core moiety comprising at least 2 carbon atoms, which may optionally further comprise one or more heteroatoms selected from N and O, wherein the core moiety is substituted with at least 2 hydroxyl groups per molecule and each hydroxyl group is attached to a different carbon atom of the core moiety. Suitable polyols are known and include, for example, alkylene glycols, such as ethylene glycol, propylene glycols, and butanediols, alkylene oxide oligomers, such as diethylene glycol, triethylene glycol, tetraethylene glycol, dipropylene glycol, and polyalkylene glycols, such as polyethylene glycol and polypropylene glycol, provided that such polyalkylene glycol is liquid at the reaction temperature, triols, such as, for example, glycerol, trimethylolpropane, triethanolamine, and trihydroxymethylaminomethane, and compounds having more than 3 hydroxyl groups per molecule, as well as mixtures of two or more of any of such compounds.

Suitable silver compounds are known and include silver oxide, silver hydroxide, organic silver salts, and inorganic silver salts, such as silver nitrate, silver nitrite, silver sulfate, silver halides such as silver chloride, silver carbonates, silver phosphate, silver tetrafluoroborate, silver sulfonate, silver carboxylates, such as, for example, silver formate, silver acetate, silver propionate, silver butanoate, silver trifluoroacetate, silver acetacetonate, silver lactate, silver citrate, silver glycolate, silver tosylate, silver tris(dimethylpyrazole)borate, as well as mixtures of two or more of such compounds.

Suitable organic protective agents are known and include one or more vinylpyrrolidone polymers selected from vinylpyrrolidone homopolymers and vinyl pyrrolidone copolymers, in each case typically having a weight average molecular weight of from about 10,000 to about 1,500,000 grams per mole (g/mol), more typically 10,000 to 200,000 g/mol. Suitable vinyl pyrrolidione copolymers comprise monomeric units derived from vinylpyrrolidone and monomeric units derived from an ethylenically unsaturated aromatic comonomer, such as for example, vinyl pyrrolidone/styrene copolymers and vinlypyrrolidone/styrene sulfonic acid copolymers.

Suitable sources of chloride and/or bromide ions include hydrochloric acid, chloride salts, such as ammonium chloride, calcium chloride, ferric chloride, lithium chloride, potassium chloride, sodium chloride, triethylbenzyl ammonium chloride, tetrabutyl ammonium chloride, hydrobromic acid, and bromide salts, such as ammonium bromide, calcium bromide, ferric bromide, lithium bromide, potassium bromide, sodium bromide, triethylbenzyl ammonium bromide, tetrabutyl ammonium bromide. In one embodiment, the source of chloride ions is lithium chloride.

The method typically produces a high yield of silver nanowires. In one embodiment, greater than or equal to 70 wt % of silver feed is converted to nanowires and less than 30 wt % of silver feed is converted to isotropic nanoparticles, more typically greater than or equal to 80 wt % of silver feed is converted to nanowires and less than 20 wt % of silver feed is converted to isotropic nanoparticles, and even more typically more than 90 wt % of silver feed is converted to nanowires and less than 10 wt % of silver feed is converted to isotropic nanoparticles.

In one embodiment, the silver nanowires made by the process of the present invention having an average diameter of from 5 nm to 200 nm, more typically from 5 nm, or from 10 nm, or from 20 nm, or from 25 nm, or from 30 nm, to 150 nm, or to 100 nm, or to 75 nm, or to 60 nm, or to 55 nm, or to 50 nm, or to 45 nm, or to 44 nm, or to 42 nm, or to 40 nm, or to less than 40 nm, and an average aspect ratio, of greater than 100, or greater than 150, or greater than 200, or greater than 300, or greater than 400.

In one embodiment, silver nanowires are provided in the form of a dispersion comprising silver nanowires dispersed in aqueous medium.

In one embodiment, the nanowire dispersion comprises silver nanowires dispersed in aqueous medium wherein the dispersion comprises based on 100 pbw of the silver nanowires, less than 1 pbw, or less than 0.5 pbw, or less than 0.1 pbw, of vinylpyrrolidone polymer. In one embodiment, the dispersion comprises no detectable amount of vinylpyrrolidone polymer.

In one embodiment, the nanowire dispersion comprises silver nanowires dispersed in a liquid medium that comprises (C₁-C₆)alkanol and less than 500 pbw, or less than 100 pbw, or less than 10 pbw, or less than 5 pbw or less than 1 pbw polyvinylpyrrolidone per 1,000,000 pbw of the nanowires.

In one embodiment, the silver nanowires are initially provided as a liquid dispersion of the nanowires that comprises a vinylpyrrolidone polymer, such as polyvinylpyrrolidone, the nanowires are, prior to incorporating the nanowires in the composition of the present invention or otherwise using the nanowires to make a film according to the present invention, treated to remove the vinyl pyrrolidone polymer. For example, polyvinyl pyrrolidone-comprising liquid dispersion of nanowires is diluted with an organic solvent, such as acetone, in which polyvinyl pyrrolidone is soluble and then the nanowires are separated from the diluted dispersion by, for example, centrifugation or filtration, and then redispersed in a second liquid medium, such as, for example, acetone, a (C₁-C₆)alkanol, or an aqueous medium, that does not comprise polyvinyl pyrrolidone. In one embodiment, the dispersion of nanowires in the second liquid medium is centrifuged to separate the nanowires from the second liquid medium and the nanowires are redispersed in another volume of the second liquid medium. In one embodiment, the cycle of centrifugation, separation, and redispersion in the second liquid medium is repeated at least one more iteration.

In one embodiment, the silver nanowires are initially provided as a dispersion in a liquid medium comprising a glycol wherein the dispersion further comprises vinyl pyrrolidone polymer, the dispersion is diluted with acetone, the diluted dispersion is centrifuged or allowed to settle by gravity to separate the nanowires from the liquid medium of the diluted dispersion, and the separated nanowires are redispersed in ethanol. In one embodiment, the dispersion of nanowires in ethanol is centrifuged or allowed to settle to separate the nanowires from the ethanol medium and the nanowires are then redispersed in another volume of ethanol. In one embodiment, the cycle of centrifugation or settling, separation, and redispersion in the second liquid medium is repeated at least one more iteration.

In one embodiment, the silver nanowires are initially provided as a dispersion in a liquid medium comprising glycol wherein the dispersion further comprises a vinyl pyrrolidone polymer, the dispersion is diluted with water, an alcohol, typically, one or more (C₁-C₆)alkanol, or a mixture water and an alchol, typically one or more (C₁-C₆)alkanol, the diluted dispersion is centrifuged or allowed to settle by gravity to separate the nanowires from the liquid medium of the diluted dispersion, and the separated nanowires are redispersed in water, alcohol, or a mixture of water and alcohol. In one embodiment, the re-dispersed nanowires centrifuged or allowed to settle by gravity to separate the nanowires from the water or water/alkanol medium and the nanowires are then re-dispersed in another volume of water, alcohol, or water/alcohol medium. In one embodiment, the cycle of centrifugation or settling, separation, and redispersion in the water, alcohol, or water/alcohol medium is repeated at least one more iteration. In those cases where the medium comprises water, the medium may optionally further comprise a surfactant. In one embodiment, the water or water/alcohol medium comprises a non-ionic surfactant, more typically one or more alkaryl alkoxylate, such as nonylphenol ethoxylates, octylphenol polyethoxylates, or a mixture thereof, typically in an amount, based on 100 pbw of the water or water/alcohol medium, from 0.05 pbw to 5 pbw of the non-ionic surfactant.

Silver nanowires made according to the process of the present invention were found to be easier to clean of vinylpyrrolidone residues, using the above describe cleaning processes, than analogous silver nanowires synthesized using prior art process conditions, for example, silver nanowires synthesized at 160° C.

In one embodiment the dispersion of the present invention comprises liquid medium and, based on 100 pbw of the dispersion, greater than 0 to about 5 pbw, more typically from about 0.1 to about 5 pbw, of silver nanowires dispersed in the medium, wherein the nanowires have an average diameter of less than or equal to 60 nm, more typically from 5 nm, or from 10 nm, or from 20 nm, or from 25 nm, or from 30 nm, to 55 nm, or to 50 nm, or to 45 nm, or to 44 nm, or to 42 nm, or to 40 nm or to less than 40 nm, and an average aspect ratio of greater than 100, or greater than 150, or greater than 200, or greater than 300 and the dispersion comprises less than or equal to 1 pbw, or less than or equal to 0.5 pbw, or less than or equal to 0.1 pbw vinylpyrrolidone polymer per 100 pbw of the silver nanostructures. More typically, the dispersion of silver nanostructures comprises no detectable amount of homopolymers or copolymers of vinylpyrrolidone.

Reducing the amount of or eliminating the homopolymers or copolymers of vinylpyrrolidone from the dispersion of silver nanowires is of great benefit in using the silver nanowires to easily make electrically conductive polymer films having very high conductivity. The silver nanowires of the dispersion of the present invention can be used to make polymer films having high electrical conductivity without requiring the extra steps required by prior art processes, such as heat treating or heating and compressing the silver nanowire network, to displace a coating of vinylpyrrolidone protective agent from the surfaces of the nanowires and allow metal to metal contact between the nanowires of the network.

In one embodiment, the liquid medium of the dispersion comprises water. In one embodiment, the liquid medium of the dispersion comprises a (C₁-C₆)alcohol, such as ethanol. In one embodiment, the liquid medium of the dispersion is an aqueous medium that comprises water and from greater than 0 to less than 100 pbw, more typically from about 1 to about 50 pbw, and even more typically from about 5 to 20 pbw of a (C₁-C₆)alcohol. The presence of the alcohol component in the liquid medium of the dispersion is of benefit in reducing oxidation of the silver nanostructure component of the dispersion.

In one embodiment, the dispersion of silver nanowires further comprises one or more surfactants, more typically one or more non-ionic surfactants. Suitable non-ionic surfactants include alkaryl alkoxylate surfactants, such as, for example, nonylphenol ethoxylates, octylphenol polyethoxylates, or a mixture thereof, to stabilize the dispersion of silver nanowires. Absent the surfactant component, the nanowires of the dispersion tend to agglomerate and to become difficult to redisperse in the liquid medium. The nanowire component of the dispersion tends to settle from the liquid medium and surfactant component of the dispersion tends to prevent agglomeration of the nanowires and allow redispersion of the nanowires in the liquid medium by agitating the dispersion.

In one embodiment, the respective polymer composition, polymer film, and polymer film component of the electronic device of the present invention further comprises one or more additional components, such as, for example one or more of polymers, dyes, coating aids, conductive particles, conductive inks, conductive pastes, charge transport materials, crosslinking agents, and combinations thereof, that are dissolved or dispersed in the liquid carrier.

In one embodiment, the polymer composition, polymer film, and polymer film component of the electronic device of the present invention further comprise one or more electrically conductive additives, such as, for example, metal particles, including metal nanoparticles, graphite particles, including graphite fibers, or carbon particles, including carbon fullerenes and carbon nanotubes, and as well as combinations of any such additives, in addition to the anisotropic electrically conductive nanostructure component. Suitable fullerenes include for example, C60, C70, and C84 fullerenes, each of which may be derivatized, for example with a (3-methoxycarbonyl)-propyl-phenyl (“PCBM”) group, such as C60-PCBM, C-70-PCBM and C-84 PCBM derivatized fullerenes. Suitable carbon nanotubes include single wall carbon nanotubes having an armchair, zigzag or chiral structure, as well as multiwall carbon nanotubes, including double wall carbon nanotubes, and mixtures thereof.

In one embodiment, the polymer composition of the present invention is made by dissolving or dispersing the electrically conductive polymer in the liquid medium and dispersing the anisotropic electrically conductive nanostructures in the liquid carrier, typically by adding the electrically conductive polymer and anisotropic electrically conductive nanostructures to the liquid carrier and agitating the mixture to form the dispersion.

In one embodiment, an electrically conductive polymer film according to the present invention is made from the polymer dispersion of the present invention by depositing a layer of the polymer composition of the present invention by, for example, casting, spray coating, spin coating, gravure coating, curtain coating, dip coating, slot-die coating, ink jet printing, gravure printing, or screen printing, on a substrate and removing the liquid carrier from the layer. Typically, the liquid carrier is removed from the layer by allowing the liquid carrier component of the layer to evaporate. The substrate supported layer may be subjected to elevated temperature to encourage evaporation of the liquid carrier.

The substrate may be rigid or flexible and may comprise, for example, a metal, a polymer, a glass, a paper, or a ceramic material. In one embodiment, the substrate is a flexible plastic sheet.

The polymer film may cover an area of the substrate that is as large as an entire electronic device or as small as a specific functional area such as the actual visual display, or as small as a single sub-pixel. In one embodiment, the polymer film has a thickness of from greater than 0 to about 10 μm, more typically from 0 to about 50 nm.

In one embodiment, the polymer film of the present invention is not redispersible in the liquid carrier, and the film can thus be applied as a series of multiple thin films. In addition, the film can be overcoated with a layer of different material dispersed in the liquid carrier without being damaged.

In one embodiment, the polymer composition of the present invention comprises, based on 100 pbw of the polymer composition:
(i) from greater than 0 to less than 100 pbw, more typically from about 50 to less than 100 pbw, even more typically from about 90 to about 99.5 pbw of a liquid carrier,
(ii) from greater than 0 to less than 100 pbw of electrically conductive polymer and anisotropic electrically conductive nanostructures, comprising, based on the combined amount of the electrically conductive polymer and anisotropic electrically conductive nanostructures:
   (a) from about 1 to about 99 pbw, more typically from about 50 to about 95 pbw, and even more typically 70 to about 92.5. pbw of the electrically conductive polymer, more typically of an electrically conductive polymer comprising, based on 100 pbw of the electrically conductive polymer:
      (1) from greater than 0 pbw to 100 pbw, more typically from about 10 to about 50 pbw, and even more typically from about 20 to about 50 pbw of one or more polythiophene polymers comprising monomeric units according to structure (I.a) wherein Q is S, and more typically, one or more polythiophene polymers comprising poly(3,4-ethylenedioxythiophene), and
      (2) from 0 pbw to 100 pbw, more typically from about 50 to about 90 pbw, and even more typically from about 50 to about 80 pbw, of one or more water soluble polymeric acid dopants, more typically of one or more water soluble polymeric acid dopants comprising a poly(styrene sulfonic acid) dopant, and
   (b) from about 1 to about 99 pbw, more typically from about 5 to about 50 pbw, even more typically from about 7.5 to about 30 pbw of the anisotropic electrically conductive nanostructures, more typically, of anisotropic electrically conductive nanostructures comprising silver nanowires, carbon nanofibers, or a mixture thereof.

In one embodiment, the anisotropic electrically conductive nanostructure component of the respective polymer film the present invention and/or polymer film component of the electronic device of the present invention comprises silver nanowires made according to the method of the present invention for making silver nanowires.

In one embodiment, the polymer composition of the present invention comprises, based on 100 pbw of the polymer composition:
(a) from about 70 to about 99.9 pbw, more typically from about 95 to about 99.5 pbw, even more typically from about 97 to about 99 pbw of liquid carrier,
(b) from about 0.1 to about 28 pbw, more typically from about 0.5 to about 5 pbw, even more typically from about 0.7 to about 2.8 pbw, of the electrically conductive polymer, and
(c) from about 0.1 to about 10 pbw, more typically from about 0.01 to about 4.5 pbw, even more typically from about 0.075 to about 1.0 pbw of the anisotropic electrically conductive nanostructures selected from silver nanowires, carbon nanofibers and mixtures thereof.

In one embodiment, respective polymer film of the present invention and polymer film component of the electronic device of the present invention each comprise, based on 100 pbw of the polymer film:
(i) from about 1 to about 99 pbw, more typically from about 50 to about 95 pbw, and even more typically from about 70 to about 92.5 pbw of the electrically conductive polymer, and
(ii) from about 1 to about 99 pbw, more typically from about 5 to about 50 pbw, and even more typically from about 7.5 to about 30 pbw of the anisotropic electrically conductive nanostructures selected from silver nanowires, carbon nanofibers and mixtures thereof.

In one embodiment, the respective polymer film of the present invention and polymer film component of the electronic device of the present invention comprises, based on 100 pbw of the polymer film:
(a) from about 1 to about 99 pbw, more typically from about 50 to about 95 pbw, and even more typically 70 to about 92.5. pbw of the electrically conductive polymer, more typically of an electrically conductive polymer comprising, based on 100 pbw of the electrically conductive polymer:
   (1) from greater than 0 pbw to 100 pbw, more typically from about 10 to about 50 pbw, and even more typically from about 20 to about 50 pbw of one or more polythiophene polymers comprising monomeric units according to structure (I.a) wherein Q is S, and more typically, one or more polythiophene polymers comprising poly(3,4-ethylenedioxythiophene), and
   (2) from 0 pbw to 100 pbw, more typically from about 50 to about 90 pbw, and even more typically from about 50 to about 80 pbw, of one or more water soluble polymeric acid dopants, more typically of one or more water soluble polymeric acid dopants comprising a poly(styrene sulfonic acid) dopant, and
(b) from about 1 to about 99 pbw, more typically from about 5 to about 50 pbw, even more typically from about 7.5 to about 30 pbw of the anisotropic electrically conductive nanostructures, more typically of anisotropic electrically conductive nanostructures comprising silver nanowires, carbon nanofibers, or a mixture thereof.

In one embodiment, the respective polymer film of the present invention and polymer film component of the electronic device of the present invention comprises, based on 100 pbw of the polymer film:
(a) from about 1 to about 99 pbw, more typically from about 50 to about 95 pbw, and even more typically 70 to about 92.5 pbw of an electrically conductive polymer, comprising, based on 100 pbw of the electrically conductive polymer:
   (1) from about 20 to about 50 pbw of poly(3,4-ethylenedioxythiophene), and
   (2) from about 50 to about 80 pbw of poly(styrene sulfonic acid) dopant, and
   (b) from about 1 to about 99 pbw, more typically from about 5 to about 50 pbw, even more typically from about 7.5 to about 30 pbw of anisotropic electrically conductive nanostructures, more typically of anisotropic electrically conductive nanostructures comprising silver nanowires, carbon nanofibers, or a mixture thereof, even more typically, comprising silver nanowires having an average diameter of from about 10 to about 150 nm and an average length of from about 10 to about 100 μm, wherein, in the embodiments comprising silver nanowires, the film typically comprises, based on 100 parts by weigh of the silver nanowires, less than 1 part by weight of vinylpyrrolidone polymer.

In one embodiment, the polymer film of the present invention comprises silver nanowires dispersed in a matrix comprising an electrically conductive polymer, wherein the film comprises, based on 100 parts by weigh of the silver nanowires, less than 1 part by weight of vinylpyrrolidone polymer.

In one embodiment, the film comprises, based on 100 pbw of the film, from 1 pbw to 35 pbw silver nanowires and from 65 pbw to 99 pbw of the polymer.

In one embodiment, the silver nanowires of the film form a network, wherein one or more of the nanowires, more typically each of a majority of the nanowires, and even more typically each of the nanowires, is in physical contact with at least one of the other nanowires.

In one embodiment, the polymer film of the present invention comprises carbon nanofibers dispersed in a matrix comprising an electrically conductive polymer.

In one embodiment, the film comprises, based on 100 pbw of the film, from 1 pbw to 35 pbw carbon nanofibers and from 65 pbw to 99 pbw of the polymer.

In one embodiment, the carbon nanofibers of the film form a network, wherein one or more of the nanofibers, more typically each of a majority of the nanofibers, and even more typically each of the nanofibers, is in physical contact with at least one of the other nanofibers.

In one embodiment, the respective polymer film the present invention and/or polymer film component of the electronic device of the present invention comprises silver nanowires.

In one embodiment, the respective polymer film the present invention and/or polymer film component of the electronic device of the present invention comprises silver nanowires made according to the method of the present invention for making silver nanowires.

The polymer film according to the present invention typically exhibits high conductivity and high optical transparency and is useful as a layer in an electronic device in which the high conductivity is desired in combination with optical transparency.

In one embodiment, the respective polymer film of the present invention and polymer film component of the electronic device of the present invention each exhibit a sheet resistance of less than or equal to 1000 Ohms per square (“Ω/□”), or less than or equal to 500Ω/□, or less than or equal to 200Ω/□, or less than or equal to 125Ω/□, or less than or equal to 100Ω/□, or less than or equal to 50Ω/□, or less than or equal to 20Ω/□, or less than or equal to 15Ω/□, or less than or equal to 10Ω/□, or less than or equal to 5Ω/□, or less than or equal to 1Ω/□

In one embodiment, wherein the respective polymer film of the present invention and polymer film component of the electronic device of the present invention comprise silver nanowires, typically from greater than 0 to about 50 pbw, or to about 40 pbw or to about 30 pbw, silver nanowires per 100 pbw of the film, the respective films each exhibit a sheet resistance of:
if the film comprises an amount of nanowires that is less than or equal to X₁ pbw silver nanowires per 100 pbw of the film, wherein X₁ is a number equal to (1050/the average aspect ratio for the nanowires), less than or equal to that calculated according to Equation (2.1):

SR=−62.4 X+308 Eq. (2.1), or
if the film comprises greater than X₁ pbw silver nanowires per 100 pbw of the film, less than or equal to that calculated according to Equation (2.2):

SR=−2.8 X+B₁ Eq. (2.2)
wherein:
   SR is the sheet resistance, expressed in Ω/□, and
   X is the amount of silver nanowires in the film, expressed as pbw of the silver nanowires per 100 pbw of the film, and
   B₁ is 175, or 150, or 125, or 100.
      Exemplary values of average aspect ratio and corresponding values of X₁ are given in the following table:

| Average Aspect Ratio | X₁ |
|---|---|
| 100 | 10.5 |
| 150 | 7 |
| 200 | 5.25 |
| 250 | 4.2 |
| 300 | 3.5 |
| 350 | 3 |
| 400 | 2.6 |
| 450 | 2.3 |
| 500 | 2.1 |

For example, in an embodiment of the polymer film of the present invention wherein the film comprises 10 pbw silver nanowires per 100 pbw of the film, the silver nanowires have an average aspect ratio of 200, and B₁ is 150, the film would exhibit a surface resistance less than or equal to −2.8 (10)+150=122 Ω/□.

In one embodiment, wherein the respective polymer film of the present invention and polymer film component of the electronic device of the present invention comprise greater than or equal to 2 pbw greater than or equal to 2.5 pbw, or greater than or equal to 3 pbw, greater than or equal to 3.5 pbw, or greater than or equal to 4 pbw, greater than or equal to 4.5 pbw, or greater than or equal to 5 pbw to about 50 pbw, or to about 40 pbw, or to about 30 pbw, silver nanowires per 100 pbw of the film each exhibit a sheet resistance of less than or equal to that calculated according to Equation (2.2) above.

In one embodiment, the respective polymer film of the present invention and polymer film component of the electronic device of the present invention each exhibit an optical transmittance at 550 nm of greater than or equal to 1%, or greater than or equal to 50%, or greater than or equal to 70%, or greater than or equal to 75%, or greater than or equal to 80%, or greater than or equal to 90%.

In one embodiment, wherein the respective polymer film of the present invention and polymer film component of the electronic device of the present invention comprise silver nanowires, typically from greater than 0 to about 50 pbw, or to about 40 pbw or to about 30 pbw, silver nanowires per 100 pbw of the film, the respective films, the respective films each exhibit optical transmittance at 550 nm of greater than or equal to that calculated according to Equation (3):

T=−0.66 X+B₂ Eq. (3)

wherein:
T is the optical transmittance, expressed as a percent (%), and
X is the amount of silver nanowires in the film, expressed as pbw of the silver nanowires per 100 pbw of the film, and
B₂ is 50, or 55, or 60, or 65, or 70, or 75, or 80, or 85, or 90, or 95.

In one embodiment, the respective polymer film of the present invention and polymer film component of the electronic device of the present invention each exhibit a sheet resistance of less than or equal to 1000Ω/□, or less than or equal to 200Ω/□, or less than or equal to 125Ω/□, or less than or equal to 100Ω/□, or less than or equal to 75Ω/□, or less than or equal to 50Ω/□, and an optical transmittance at 550 nm of greater than or equal to 50%, or greater than or equal to 70%, or than or equal to 80%, or greater than or equal to 90%.

In one embodiment, the respective polymer film of the present invention and polymer film component of the electronic device of the present invention each exhibit, for a given silver nanowire content, a sheet resistance of less than or equal to that calculated by Equation 2.1 or 2.2 above and an optical transmittance at 550 nm of greater than or equal to that calculated according to Equation (3) above.

In one embodiment, wherein the respective polymer film of the present invention and polymer film component of the electronic device of the present invention comprise greater than or equal to 2 pbw greater than or equal to 2.5 pbw, or greater than or equal to 3 pbw, greater than or equal to 3.5 pbw, or greater than or equal to 4 pbw, greater than or equal to 4.5 pbw, or greater than or equal to 5 pbw to about 50 pbw, or to about 40 pbw or to about 30 pbw, silver nanowires per 100 pbw of the film each exhibit a sheet resistance of less than or equal to that calculated according to Equation (2.2) above and an optical transmittance at 550 nm of greater than or equal to that calculated according to Equation (3) above.

In one embodiment, the respective polymer film of the present invention and polymer film component of the electronic device of the present invention each exhibit a sheet resistance of less than or equal to 100Ω and an optical transmittance at 550 nm of greater than or equal to 90%.

In one embodiment, the respective polymer film of the present invention and polymer film component of the electronic device of the present invention each exhibit a sheet resistance of less than or equal to 15Ω and an optical transmittance at 550 nm of greater than or equal to 70%.

In one embodiment, the respective polymer film of the present invention and polymer film component of the electronic device of the present invention each exhibit a sheet resistance of less than or equal to 5Ω/□ and an optical transmittance at 550 nm of greater than or equal to 50%.

In one embodiment, polymer film according to the present invention is used as a layer in an electronic device.

In one embodiment, polymer film according to the present invention is used as an electrode layer, more typically, an anode layer, of an electronic device.

In one embodiment, the polymer film according to the present invention is used as a buffer layer of an electronic device.

In one embodiment, a polymer film according to the present invention is used as a combined electrode and buffer layer, typically a combined anode and buffer layer, of an electronic device.

The surface of the electrically conductive film of the present invention may, in some embodiments, exhibit some surface roughness as cast and may optionally be coated with a smoothing layer of electrically conductive polymer in order to further reduce the surface roughness to, for example, an RMS surface roughness of less than or equal to 10 nm, or less than or equal to 5 nm, or less than or equal to 1 nm, prior to using the film as layer in an electronic device.

In one embodiment, the anisotropic electrically conductive nanostructure component of the respective polymer film of the present invention and polymer film component of the electronic device of the present invention comprises silver nanowires having an average diameter of less than 60 nm, more typically from 5 nm, or 10 nm or 20 nm or 25 nm or 30 nm to 55 nm, or 50 nm, or 45 nm, or 44 nm, or 42 nm, or 40 nm, and an average aspect ratio of greater than 100, or greater than 150, or greater than 200, or greater than 300, or greater than 400 nm, exhibit low surface roughness as cast, that is, without application of a smoothing layer, such as, for example, an RMS surface roughness of less than or equal to 20 nm, or less than or equal to 15 nm, or less than or equal to 10 nm. Compared to films having higher surface roughness, the low surface roughness embodiments of the film of the present invention require a thinner smoothing layer and are more easily and dependably smoothed to provide surfaces having very low surface roughness.

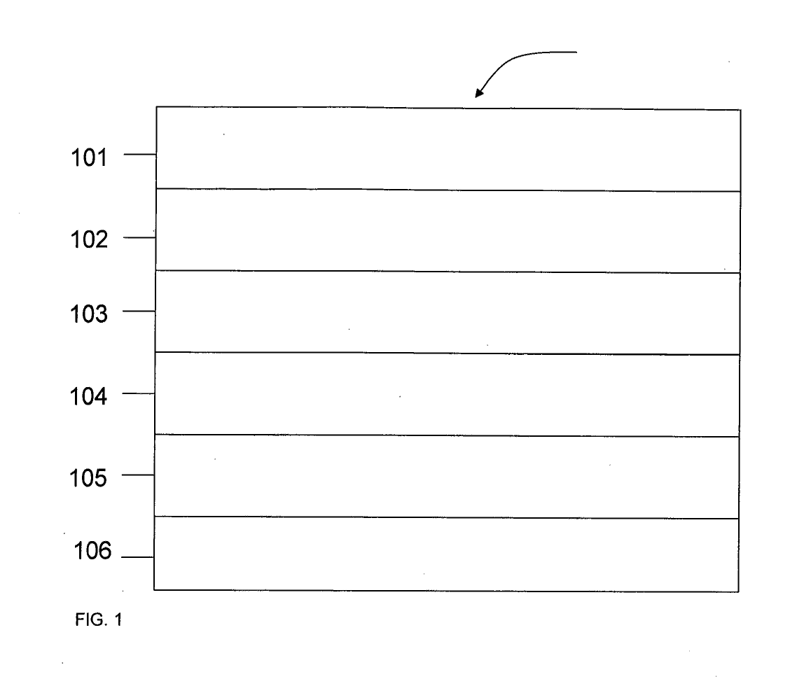

In one embodiment, the electronic device of the present invention is an electronic device 100, as shown in FIG. 1, having an anode layer 101, an electroactive layer 104, and a cathode layer 106 and optionally further having a buffer layer 102, hole transport layer 103, and/or electron injection/transport layer or confinement layer 105, wherein at least one of the layers of the device is a polymer film according to the present invention. The device 100 may further include a support or substrate (not shown), that can be adjacent to the anode layer 101 or the cathode layer 106. more typically, adjacent to the anode layer 101. The support can be flexible or rigid, organic or inorganic. Suitable support materials include, for example, glass, ceramic, metal, and plastic films.

In one embodiment, anode layer 101 of device 100 comprises a polymer film according to the present invention. The polymer film of the present invention is particularly suitable as anode layer 106 of device 100 because of its high electrical conductivity.

In one embodiment, anode layer 101 itself has a multilayer structure and comprises a layer of the polymer film according to the present invention, typically as the top layer of the multilayer anode, and one or more additional layers, each comprising a metal, mixed metal, alloy, metal oxide, or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 101 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 101 include, but are not limited to, indium-tin-oxide (“ITO”), indium-zinc-oxide, aluminum-tin-oxide, gold, silver, copper, and nickel. The mixed oxide layer may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include radio frequency magnetron sputtering and inductively-coupled plasma physical vapor deposition (“IMP-PVD”). These deposition techniques are well known within the semiconductor fabrication arts.

In one embodiment, the mixed oxide layer is patterned. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used.

In one embodiment, device 100 comprises a buffer layer 102 and the buffer layer 102 comprises a polymer film according to the present invention.

In one embodiment, a separate buffer layer 102 is absent and anode layer 101 functions as a combined anode and buffer layer. In one embodiment, the combined anode/buffer layer 101 comprises a polymer film according to the present invention.

In some embodiments, optional hole transport layer 103 is present, either between anode layer 101 and electroactive layer 104, or, in those embodiments that comprise buffer layer 102, between buffer layer 102 and electroactive layer 104. Hole transport layer 103 may comprise one or more hole transporting molecules and/or polymers. Commonly used hole transporting molecules include, but are not limited to: 4,4′,4″-tris(N,N-diphenyl-amino)-triphenylamine (TDATA), 4,4′,4″-tris(N-3-methylphenyl-N-phenyl-amino)-triphenylamine (MTDATA), N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)bip-henyl]-4,4′-diamine (ETPD), tetrakis-(3-methylphenyl)-N,N,N′,N′-2,5-phenylenediamine (PDA), .alpha.-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyr-azoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (.alpha.-NPB), and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules, such as those mentioned above, into polymers such as polystyrene and polycarbonate.

The composition of electroactive layer 104 depends on the intended function of device 100, for example, electroactive layer 104 can be a light-emitting layer that is activated by an applied voltage (such as in a light-emitting diode or light-emitting electrochemical cell), or a layer of material that responds to radiant energy and generates a signal with or without an applied bias voltage (such as in a photodetector). In one embodiment, electroactive layer 104 comprises an organic electroluminescent (“EL”) material, such as, for example, electroluminescent small molecule organic compounds, electroluminescent metal complexes, and electroluminescent conjugated polymers, as well as mixtures thereof. Suitable EL small molecule organic compounds include, for example, pyrene, perylene, rubrene, and coumarin, as well as derivatives thereof and mixtures thereof. Suitable EL metal complexes include, for example, metal chelated oxinoid compounds, such as tris(8-hydroxyquinolate)aluminum, cyclo-metallated iridium and platinum electroluminescent compounds, such as complexes of iridium with phenylpyridine, phenylquinoline, or phenylpyrimidine ligands as disclosed in Petrov et al., U.S. Pat. No. 6,670,645, and organometallic complexes such as those described in, for example, Published PCT Applications WO 03/008424, WO 03/091688, and WO 03/040257, as well as mixtures any of such EL metal complexes. Examples of EL conjugated polymers include, but are not limited to poly(phenylenevinylenes), polyfluorenes, poly(spirobifluorenes), polythiophenes, and poly(p-phenylenes), as well as copolymers thereof and mixtures thereof.

Optional layer 105 can function as an electron injection/transport layer and/or a confinement layer. More specifically, layer 105 may promote electron mobility and reduce the likelihood of a quenching reaction if layers 104 and 106 would otherwise be in direct contact. Examples of materials suitable for optional layer 105 include, for example, metal chelated oxinoid compounds, such as bis(2-methyl-8-quinolinolato)(para-phenyl-phenolato)aluminum(III) (BAIQ) and tris(8-hydroxyquinolato)aluminum, tetrakis(8-hydroxyquinolinato)zirconium, azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI), quinoxaline derivatives such as 2,3-bis(4-fluorophenyl)quinoxaline, phenanthroline derivatives such as 9,10-diphenylphenanthroline (DPA) and 2,9-dimethyl-4,7-diphenyl-1,10-phenanthroline (DDPA), and as well as mixtures thereof. Alternatively, optional layer 105 may comprise an inorganic material, such as, for example, BaO, LiF, Li₂O.

Cathode layer 106 can be any metal or nonmetal having a lower work function than anode layer 101. In one embodiment, anode layer 101 has a work function of greater than or equal to about 4.4 eV and cathode layer 106 has a work function less than about 4.4 eV. Materials suitable for use as cathode layer 106 are known in the art and include, for example, alkali metals of Group 1, such as Li, Na, K, Rb, and Cs, Group 2 metals, such as, Mg, Ca, Ba, Group 12 metals, lanthanides such as Ce, Sm, and Eu, and actinides, as well as aluminum, indium, yttrium, and combinations of any such materials. Specific non-limiting examples of materials suitable for cathode layer 106 include, but are not limited to, Barium, Lithium, Cerium, Cesium, Europium, Rubidium, Yttrium, Magnesium, Samarium, and alloys and combinations thereof. Cathode layer 106 is typically formed by a chemical or physical vapor deposition process. In some embodiments, the cathode layer will be patterned, as discussed above in reference to the anode layer 101.

In one embodiment, an encapsulation layer (not shown) is deposited over cathode layer 106 to prevent entry of undesirable components, such as water and oxygen, into device 100. Such components can have a deleterious effect on electroactive layer 104. In one embodiment, the encapsulation layer is a barrier layer or film. In one embodiment, the encapsulation layer is a glass lid.

Though not shown in FIG. 1, it is understood that device 100 may comprise additional layers. Other layers that are known in the art or otherwise may be used. In addition, any of the above-described layers may comprise two or more sub-layers or may form a laminar structure. Alternatively, some or all of anode layer 101, buffer layer 102, hole transport layer 103, electron transport layer 105, cathode layer 106, and any additional layers may be treated, especially surface treated, to increase charge carrier transport efficiency or other physical properties of the devices. The choice of materials for each of the component layers is typically determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

The various layers of the electronic device can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing. Other layers in the device can be made of any materials which are known to be useful in such layers upon consideration of the function to be served by such layers.

In one embodiment of the device 100, the different layers have the following range of thicknesses:

anode layer 101, typically 500-5000 Angstroms (“Å”), more typically, 1000-2000 Å,

optional buffer layer 102: typically 50-2000 Å, more typically, 200-1000 Å,

optional hole transport layer 103: typically 50-2000 Å, more typically, 100-1000 Å,

photoactive layer 104: typically, 10-2000 Å, more typically, 100-1000 Å,

optional electron transport layer: typically 105, 50-2000 Å, more typically, 100-1000 Å, and

cathode layer 106: typically 200-10000 Å, more typically, 300-5000 Å.

As is known in the art, the location of the electron-hole recombination zone in the device, and thus the emission spectrum of the device, can be affected by the relative thickness of each layer. The appropriate ratio of layer thicknesses will depend on the exact nature of the device and the materials used.

In one embodiment, the electronic device of the present invention, comprises:
(a) an anode or combined anode and buffer layer 101,
(b) a cathode layer 106,
(c) an electroactive layer 104, disposed between anode layer 101 and cathode layer 106,
(d) optionally, a buffer layer 102, typically disposed between anode layer 101 and electroactive layer 104,
(e) optionally, a hole transport layer 105, typically disposed between anode layer 101 and electroactive layer 104, or if buffer layer 102 is present, between buffer layer 102 and electroactive layer 104, and
(f) optionally an electron injection layer 105, typically disposed between electroactive layer 104 and cathode layer 106,
   wherein at least one of the layers of the device, typically at least one of the anode or combined anode and buffer layer 101 and, if present, buffer layer 102 comprises a polymer film according to the present invention, that is, a polymer film comprising a mixture of:

(i) an electrically conductive polymer, and

(ii) anisotropic electrically conductive nanostructures.

The electronic device of the present invention may be any device that comprises one or more layers of semiconductor materials and makes use of the controlled motion of electrons through such one or more layers, such as, for example:

a device that converts electrical energy into radiation, such as, for example, a light-emitting diode, light emitting diode display, diode laser, or lighting panel,

a device that detects signals through electronic processes, such as, for example, a photodetector, photoconductive cell, photoresistor, photoswitch, phototransistor, phototube, infrared (“IR”) detector, or biosensor,

a device that converts radiation into electrical energy, such as, for example, a photovoltaic device or solar cell, and

a device that includes one or more electronic components with one or more semiconductor layers, such as, for example, a transistor or diode.

In one embodiment, the electronic device of the present invention is a device for converting electrical energy into radiation, and comprises an anode 101 that comprises a polymer film according to the present invention, a cathode layer 106, an electroactive layer 104 that is capable of converting electrical energy into radiation, disposed between the anode layer 101 layer and the cathode layer 106, and optionally further comprising a buffer layer 102, a hole transport layer 103, and/or an electron injection layer 105. In one embodiment, the device is a light emitting diode (“LED”) device and the electroactive layer 104 of the device is an electroluminescent material, even more typically, and the device is an organic light emitting diode (“OLED”) device and the electroactive layer 104 of the device is organic electroluminescent material. In one embodiment, the OLED device is an “active matrix” OLED display, wherein, individual deposits of photoactive organic films may be independently excited by the passage of current, leading to individual pixels of light emission. In another embodiment, the OLED is a “passive matrix” OLED display, wherein deposits of photoactive organic films may be excited by rows and columns of electrical contact layers.

In one embodiment, the electronic device of the present invention is a device for converting radiation into electrical energy, and comprises an anode 101 that comprises a polymer film according to the present invention, a cathode layer 106, an electroactive layer 104 comprising a material that is capable of converting radiation into electrical energy, disposed between the anode layer 101 layer and the cathode layer 106, and optionally further comprising a buffer layer 102, a hole transport layer 103, and/or an electron injection layer 105.

In operation of one embodiment of device 100, such as a device for converting electrical energy into radiation, a voltage from an appropriate power supply (not depicted) is applied to device 100 so that an electrical current passes across the layers of the device 100 and electrons enter electroactive layer 104, and are converted into radiation, such as in the case of an electroluminescent device, a release of photon from electroactive layer 104.

In operation of another embodiment of device 100, such as device for converting radiation into electrical energy, device 100 is exposed to radiation impinges on electroactive layer 104, and is converted into a flow of electrical current across the layers of the device.

### Examples 1-16 and Comparative Example C1

The dispersions and polymer films of Examples 1 to 16 and Comparative Example C1 were made as follows.

A dispersion of PEDOT:PSS polymer in water and dimethyl sulfoxide (“DMSO”) was made as follows. 11.11 g of a 18% poly(styrene sulfonic acid) PSSH solution (10.9 mmol of monomer) was dissolved in 85 mL of deionized water, 80 mg (5.6 mmol) of EDOT was added. After stirring vigorously, 1.8 g of potassium persulfate (6.2 mmol) where added in the reactor. Then, 150 μL of a 10% FeCl₃.6H₂O solution (0.055 mmol) was added. Polymerization of the EDOT was observed while stirring gently for 24 hours. The polymer particles were separated from the reaction medium by centrifuging (15000 rpm, 30 min) and washed three times with water. The polymer concentration was adjusted to be 1.4% by weight. 10 g of ion-exchange resin (J. T. Baker IONAC® NM-60 H⁺/OH⁻ Form, Type I, Beads (16-50 Mesh)) were then added to the samples, which were put on the rotating wheel for 3 days. The samples were then filtered from the ion exchange resin. 7 ml of DMSO was added per 100 ml of 1.4% PEDOT:PSS, to form the PEDT:PSS dispersion.

The PEDOT:PSS dispersion were combined with silver nanowires to form the dispersions of Examples 1-16, each of which contained 1.25 wt % of a combined amount of PEDOT:PSS and silver nanowires dispersed in a 75/20/5 mixture of water/ethyl alcohol/DMSO,

For the dispersions and films of Examples 1-8, the silver nanowires (“Nanowires-1”) were synthesized in ethylene glycol in the presence of AgCl particles and polyvinylpyrrolidone at 180° C. in general accordance with the method described by: C. DUCAMP-SANGUESA, R. HERRERA-URBINA, AND M. FIGLARZ, JOURNAL OF SOLID STATE CHEMISTRY, 100, 272-280 (1992). The resultant nanowire suspension was diluted in acetone and centrifuged at 5000 g. The supernatant, containing residual ethylene glycol, salts, and polyvinylpyrrolidone polymer, was discarded and the sediment, containing the silver nanowires, was kept. The sediment was re-suspended in ethanol, centrifuged to separate the nanowires from the ethanol, after which the supernatant was discarded and the sediment was again re-suspended in another volume of ethanol. The re-suspension/centrifugation cycle was repeated 6 times. After last re-suspension/centrifugation cycle, the silver nanowires were re-suspended in ethanol and the concentration of silver nanowires was adjusted to 1.6 weight/volume %.

For the dispersions and films of Examples 9-16, commercially available silver nanowires (“Nanowires-2”, SLV-NW-60 silver nanowires (Blue Nano Inc.)) were used. Scanning electron microscopic images were taken of the Nanowires-2, from which the average diameter of the Nanowires-2 was determined to be about 150 nm and the average length of the Nanowires-2 was determined to be more than 10 microns.

The nanowire/PEDOT:PSS:DMSO dispersions were then spin coated on flexible transparent polyester sheet at a speed of 1000, 2000, 3000, or 4000 revolutions per minute (rpm) and baked at 90° C. for 5 minutes to obtain the films. The amount of silver nanowires and amount of PEDOT:PSS for each of the dispersions of Examples 1-16 and Comparative Example C1 and for the respective films made from such dispersion are given in TABLES I and II below.

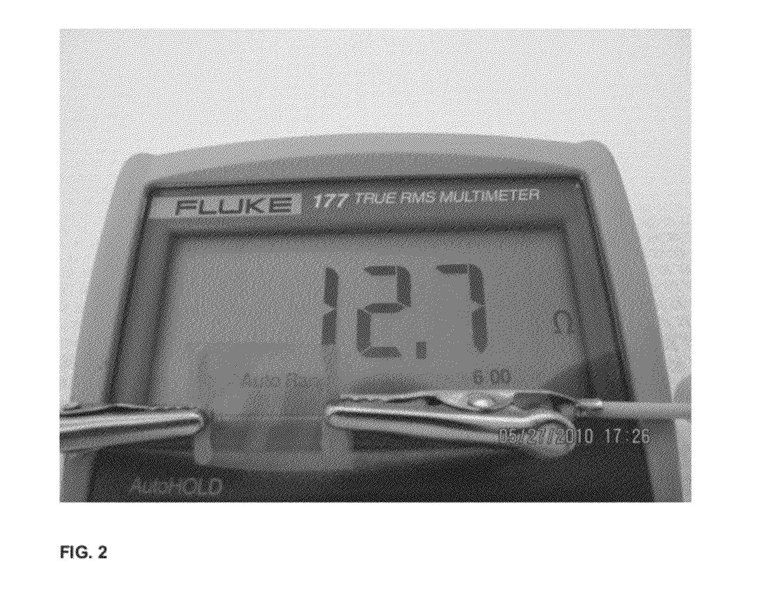

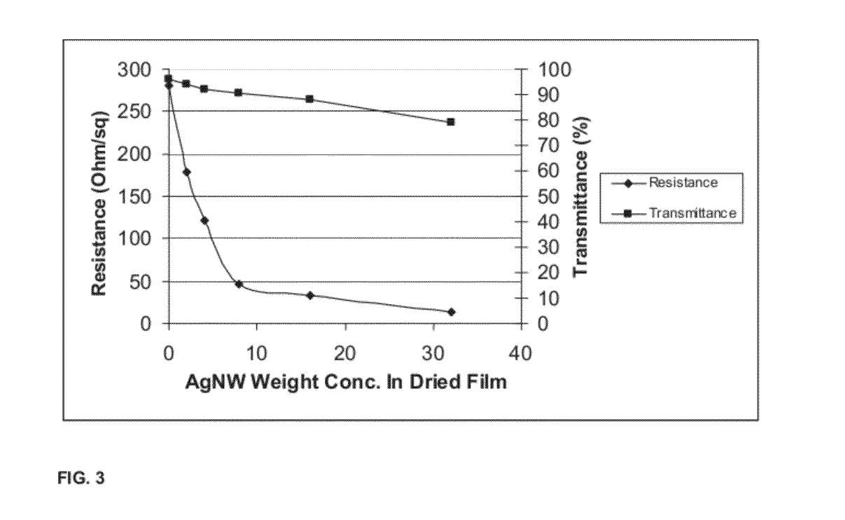

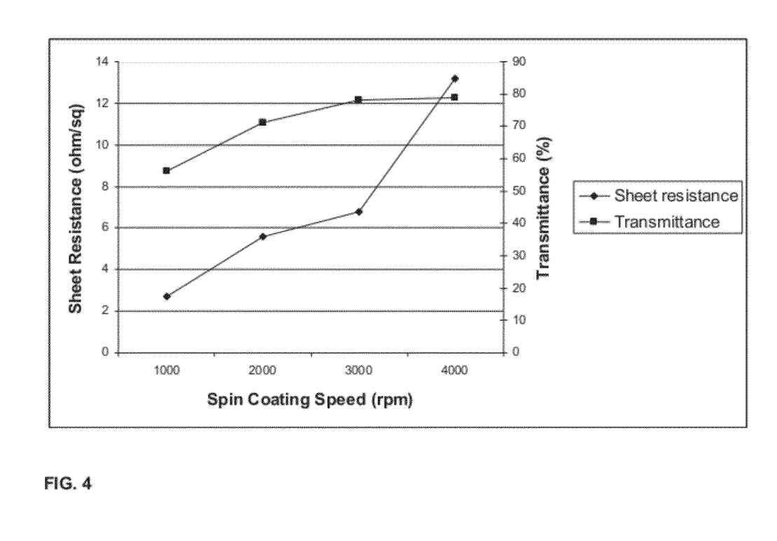

The sheet resistance of each of the films was measured using the two electrode technique as shown in FIG. 2, where the electrodes are made of silver paste. Transmittance was measured placing the films in a UV/Vis spectrophotometer, positioned so that the light passes through the sample between the silver paste lines, at a wavelength of 550 nm. The sheet resistance and transmittance results obtained for the films of Examples 1-16 and Comparative Example C1 are given in TABLES 1 and 2 below and the results for the films of Examples 9-16 are shown graphically in FIG. 3 and FIG. 4.

TABLE I

| Example # | C1 | 1 | 2 | 3 | 4 | 5 | 6 | 7 | 8 |
|---|---|---|---|---|---|---|---|---|---|
| Spin Coating | 4000 | 4000 | 4000 | 4000 | 4000 | 4000 | 3000 | 2000 | 1000 |
| Speed (rpm) | | | | | | | | | |
| Nanowires-1 | 0 | 0.025 | 0.05 | 0.1 | 0.2 | 0.4 | 0.4 | 0.4 | 0.4 |
| (wt % in dispersion) | | | | | | | | | |
| PEDOT:PSS | 1.25 | 1.225 | 1.20 | 1.15 | 1.05 | 0.85 | 0.85 | 0.85 | 0.85 |
| (wt % in dispersion) | | | | | | | | | |
| Nanowires-1 | 0 | 2 | 4 | 8 | 16 | 32 | 32 | 32 | 32 |
| (wt % in film) | | | | | | | | | |
| PEDOT:PSS | 100 | 98 | 96 | 92 | 74 | 68 | 68 | 68 | 68 |
| (wt % in film) | | | | | | | | | |
| Transmittance (%) | — | — | — | — | — | — | — | — | — |
| Sheet resistance | 280 | 230 | 200 | 90.2 | 60.4 | 40.3 | 20.1 | 16.8 | 12 |
| (ohm/square) | | | | | | | | | |

TABLE II

| Example # | C1 | 9 | 10 | 11 | 12 | 13 | 14 | 15 | 16 |
|---|---|---|---|---|---|---|---|---|---|
| Spin Coating | 4000 | 4000 | 4000 | 4000 | 4000 | 4000 | 3000 | 2000 | 1000 |
| Speed (rpm) | | | | | | | | | |
| Nanowires-2 | 0 | 0.025 | 0.05 | 0.1 | 0.2 | 0.4 | 0.4 | 0.4 | 0.4 |
| (wt % in dispersion) | | | | | | | | | |
| PEDOT:PSS | 1.25 | 1.225 | 1.20 | 1.15 | 1.05 | 0.85 | 0.85 | 0.85 | 0.85 |
| (wt % in dispersion) | | | | | | | | | |
| Nanowires-2 | 0 | 2 | 4 | 8 | 16 | 32 | 32 | 32 | 32 |
| (wt % in film) | | | | | | | | | |
| PEDOT:PSS | 100 | 98 | 96 | 92 | 74 | 68 | 68 | 68 | 68 |
| (wt % in film) | | | | | | | | | |
| Transmittance (%) | 96 | 94 | 92 | 90.6 | 88.2 | 79 | 78 | 71 | 56 |
| Sheet resistance | 280 | 179.1 | 121.7 | 47.2 | 33 | 13.2 | 6.8 | 5.6 | 2.7 |
| (ohm/square) | | | | | | | | | |

### Examples 17 and 18

The dispersions and polymer films of Examples 17 and 18 were made as follows.

A PEDOT:PSS dispersion was made as described above in regard to Examples 1-16 and Comparative Example C1.

The PEDOT:PSS dispersion was combined with carbon nanofibers to form the dispersions of Examples 19 and 20, each of which contained 1.25 wt % of a combined amount of PEDOT:PSS and carbon nanofibers dispersed in a 75/20/5 mixture of water/ethyl alcohol/DMSO, The average diameter of the carbon nanofibers was determined to be about 200 nm and the average length of the carbon nanofibers was determined to be 10 microns

The carbon nanofiber/PEDOT:PSS:DMSO suspensions were then spin coated on flexible transparent polyester sheet at a speed of 2000 or 4000 rpm and baked at 90° C. for 5 minutes to obtain the films of Examples 17 and 18. The amount of carbon nanofibers and amount of PEDOT:PSS for each of the dispersions of Examples 17 and 18 and for the respective films made from such dispersion are given in TABLE III below.

The sheet resistance and transmittance of the samples were measured as described above in regard to Examples 1-16 and Comparative Example C1. The sheet resistance and transmittance results obtained for the films of Examples 17 and 18 are given in TABLE III below

TABLE III

| Example # | C1 | 17 | 18 |
|---|---|---|---|
| Spin Coating Speed (rpm) | 4000 | 2000 | 4000 |
| Carbon nanofibers | 0 | 0.4 | 0.4 |
| (wt % in dispersion) | | | |
| PEDOT:PSS | | | |
| (wt % in dispersion) | | | |
| Carbon nanofibers | 0 | 32 | 32 |
| (wt % in film) | | | |
| PEDOT:PSS (wt % in film) | 100 | 68 | 68 |
| Transmittance (%) | 96 | 75 | 86 |
| Sheet resistance | 280 | 250 | 500 |
| (ohm/square) | | | |

### Examples 19-25

Ethylene glycol (EG), Polyvinylpyrrolidone (PVP) and lithium chloride (LiCl) were heated at 180° C. in a three-necked flask under magnetic stirring under N₂ for about 15 minutes. Then, in a solution of EG containing a small amount silver nitrate is injected within 1 minute. Precipitation (of AgCl) is observed immediately. The reaction was keep for 5 min.

Solution of EG containing a higher quantity of AgNO₃ were then injected drop wise by syringe with a pump within 20 min. The reaction was maintained for The reaction was maintained for 40 min. The product was cooled under atmospheric conditions. The amounts of ethylene glycol (“EG”), LiCl, and AgNO₃ used in the seed step and the growth step are set forth, in grams (“g”) milliliters (“mL”) and/or concentration (moles per Liter (“mol/L”), based on the final volume of reaction mixture, in TABLE IV below.

TABLE IV

| | | | | | EG with | | | |
|---|---|---|---|---|---|---|---|---|
| | Initial | | | AgNO₃seed | AgNO₃seed | AgNO₃second | EG in | Total |
| | EG | LiCl | PVP | step in EG | step | step in EG | second step | EG |
| Weight (g) | 34 | 0.0009 | 1 | 0.0045 | 2 | 0.3 | 11 | 45 |
| Concentration | 30 ml | 5.4 × 10⁻⁴ mol/l | | 6.6 × 10⁻⁴ mol/l | 2 ml | 4.4 × 10⁻² | 10 ml | 40 ml |
| in final | | | | | | | | |
| solution | | | | | | | | |
| (mol/l) or | | | | | | | | |
| volume (ml) | | | | | | | | |

The silver nanowires were then cleaned to remove EG, PVP, and any unreacted species, and to separate the nanowires from a small amount of nanoparticles side product (estimated to be considerably less than 10 wt % of the silver nanostructure content of the product mixture) by centrifuging the reaction mixture in a mixture of 90 pbw water and 10 pbw ethanol and 0.5 pbw nonionic surfactant (Triton X, Dow Chemical Company) at 500 revolutions per minute (rpm) for from 30 minutes, redispersing the nanowires in another volume of the water/ethanol/surfactant mixture, centrifuging the mixture a 500 rpm for 30 minutes and repeating the redispersing and centrifuging process 3 more times, and ending by redispersing the nanowires in another volume of the water/ethanol/surfactant mixture.

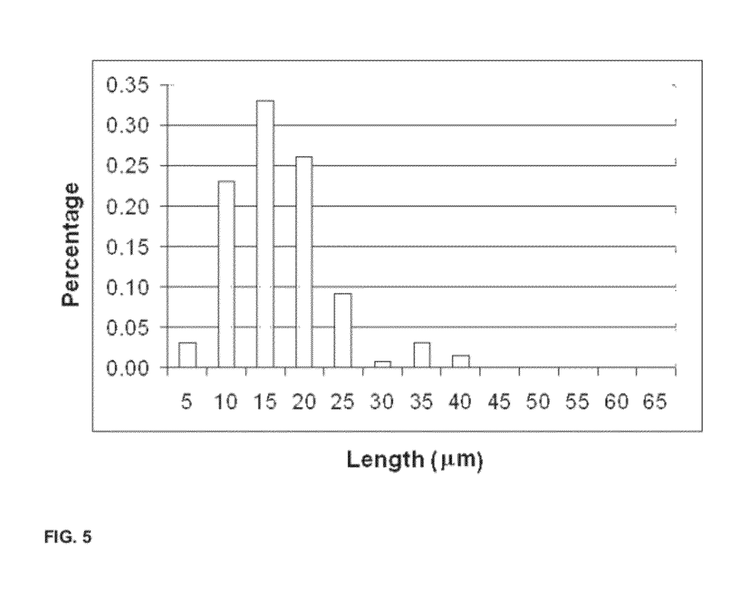

The silver nanowires of Example 19 exhibited an average diameter of 42 nm, atomic force microscopy, a weighted average length of 18 pm, as measured by optical microscopy, and an average aspect ratio of 428. The length distribution of the silver nanowires of Example 19 is shown, as a plot of percentage of nanowires versus length, in FIG. 5.

The silver nanowires of Example 19 were used to make electrically conductive polymer films according to the procedure described above in regard to Examples 1-16, and spin coated at 4000 rpm. The spin coating speed and relative amounts of PEDOT:PSS and silver nanowires are set forth in TABLE V below.

The sheet resistance and transmittance for the films of Examples 20-25 and Comparative Example C2 were measured as described above in regard to the films of Examples 1-16 and Comparative Example C1 and the results are set forth in TABLE V below.

TABLE V

| Example # | C2 | 20 | 21 | 22 | 23 | 24 | 25 |
|---|---|---|---|---|---|---|---|
| Nanowires of EX 19 | 0 | 0.0125 | 0.025 | 0.05 | 0.1 | 0.2 | 0.4 |
| (wt % in dispersion) | | | | | | | |
| PEDOT:PSS | 1.25 | 1.2375 | 1.225 | 1.2 | 1.15 | 1.05 | 0.85 |
| (wt % in dispersion) | | | | | | | |
| Nanowires of EX 19 | 0 | 1 | 2 | 4 | 8 | 16 | 32 |
| (wt % in film) | | | | | | | |
| PEDOT:PSS | 100 | 99 | 98 | 96 | 92 | 84 | 68 |
| (wt % in film) | | | | | | | |
| Transmittance (%) | 97.2 | 97.2 | 94.7 | 95.8 | 92.3 | 88.6 | 76.8 |
| Sheet resistance | 280 | 245.7 | 183.3 | 135.5 | 114.5 | 63.3 | 18.5 |
| (ohm/square) | | | | | | | |

### Examples 26 and 27

The nanowires of Example 26 were made in a manner analogous to that described above for the nanowires of Example 19, except that 0.009 g of LiCl were charged to the reactor and 0.045 g of AgNO₃ were charged to the reactor in the seed step seed step in EG. The silver nanowires exhibited an average diameter of 33 nm, atomic force microscopy, and a weighted average length of 14 μm, as measured by optical microscopy. The film of Example 27 was made in a manner analogous to that described above for Examples 20 to 25, and contained 8 wt % of the nanowires of Example 26. The surface roughness of the films of Examples 27 and 11 above were each measured using atomic force microscopy. The film of Example 27 exhibited an RMS surface roughness of 8.1, compared to a surface roughness of 26.1 for the film of Example 11.

What is claimed is:

1. A dispersion, comprising a liquid medium and, based on 100 parts by weight of the dispersion, from about 0.1 to about 5 parts by weigh of silver nanowires dispersed in the liquid medium, wherein the silver nanowires have an average diameter of less than or equal to 60 nm with an average aspect ratio of greater than 100 and the dispersion comprises, based on 100 parts by weigh of the silver nanowires, less than 1 part by weight of vinylpyrrolidone polymer.

2. The dispersion of claim 2, wherein the liquid medium comprises water, a (C1-C6)alkanol and a nonionic surfactant.

3. A method for making silver nanowires by reacting, under an inert atmosphere, at a temperature of from 170° C. to 185° C., and in the presence of particles of silver chloride or silver bromide and at least one organic protective agent:
(a) at least one polyol, and
(b) at least one silver compound that is capable of producing silver metal when reduced.

4. The method of claim 3, wherein the reaction is conducted in the presence of particles of silver chloride.

5. The method of claim 3, wherein the polyol comprises an alkylene glycol a polyalkylene glycol or a triol.

6. The method of claim 3, wherein the polyol comprises ethylene glycol.

7. The method of claim 3, wherein the organic protective agent comprises a vinylpyrrolidone copolymer.

8. The method of claim 3, wherein the at least one silver compound comprises silver oxide, silver hydroxide, organic silver salts, and inorganic silver salts.

9. The method of claim 3, wherein the at least one silver compound comprises silver nitrate.

10. The method of claim 3, wherein the reaction is conducted in the presence of particles of silver chloride, the polyol comprises ethylene glycol, the organic protective agent comprises a vinylpyrrolidone copolymer, and the at least one silver compound comprises silver nitrate.

11. The method of claim 3, further comprising washing the silver nanowires to remove the polyol and organic protective agent and redispersing the nanowires in a liquid medium comprising water.

12. Silver nanowires made by the process of claim 3.

13. A polymer film, comprising a mixture of:
(a) an electrically conductive polymer, and
(b) a network of silver nanowires,
wherein the film comprises, based on 100 parts by weigh of the silver nanowires, less than 1 part by weight of vinylpyrrolidone polymer.

14. The polymer film of claim 13, wherein the electrically conductive polymer comprises a polyaniline polymer a mixture of a polythipophene polymer and a polymeric acid dopant.

15. The polymer film of claim 14, wherein the polythiopene polymer comprises two or more monomeric units according to structure (I.a) per molecule of the polymer: 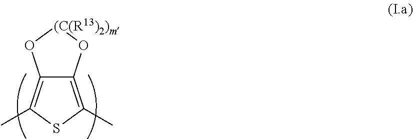
wherein:
each occurrence of R¹³ is independently H, alkyl, hydroxy, heteroalkyl, alkenyl, heteroalkenyl, hydroxalkyl, amidosulfonate, benzyl, carboxylate, ether, ether carboxylate, ether sulfonate, ester sulfonate, or urethane, and
m′ is 2 or 3.
and the polymeric acid dopant comprises poly((styrene sulfonate).

16. The polymer film of claim 13, wherein the anisotropic electrically conductive nanostructures comprise silver nanowires have an average diameter of from about 10 to about 150 nm and a length of from about 5 to about 150 μm.

17. The polymer film of claim 13, wherein the silver nanowires have an average diameter of from 5 nm to 60 nm and an average aspect ratio of greater than 100.

18. The polymer film of claim 13, wherein the film exhibits a sheet resistance of less than or equal to 150 Ohms per square.

19. The polymer film of claim 13, wherein the film exhibits a sheet resistance of less than or equal to 100 Ohms per square.

20. The polymer film of claim 13, wherein the film exhibits an exhibit a sheet resistance of:
(a) if the film comprises less than or equal to X₁ parts by weight silver nanowires per 100 parts by weight of the film, less than or equal to that calculated according to Equation (2.1):
SR=−62.4 X+308 Eq. (2.1), or
(b) if the film comprises greater than X₁ parts by weight silver nanowires per 100 parts by weight of the film, less than or equal to that calculated according to Equation (2.2):
SR=−2.8 X+B₁ Eq. (2.2)
wherein:
SR is the sheet resistance, expressed in Ohms per square
X is the amount of silver nanowires in the film, expressed as parts by weight of the silver nanowires per 100 parts by weight of the film,
X₁ is a number equal to (1050/average aspect ratio of the silver nanowires), and
B₁ is 175.

21. The polymer film of claim 13, wherein the film exhibits an optical transmittance at 550 nm of greater than or equal to 50%.

22. The polymer film of claim 13, wherein the film exhibits an optical transmittance at 550 nm of greater than or equal to 75%.

23. The polymer film of claim 13, wherein the film exhibits exhibit optical transmittance at 550 nm of greater than or equal to that calculated according to Equation (3):
T=−0.66 X+B₂ Eq. (3)
wherein:
T is the optical transmittance, expressed as a percent (%),
X is the amount of silver nanowires contained in the film, expressed as parts by weight of the silver nanowires per 100 parts by weight of the film, and
B₂ is 50.

24. The polymer film of claim 13, wherein the film is supported on a substrate.

25. A polymer film, comprising a mixture of:
(i) an electrically conductive polymer, and
(ii) a network of carbon nanofibers.

26. A polymer composition, comprising:
(a) a liquid carrier,
(b) an electrically conductive polymer dissolved or dispersed in the liquid carrier, and
(c) anisotropic electrically conductive nanostructures dispersed in the liquid carrier.

27. The polymer composition of claim 26, wherein the electrically conductive polymer comprises a polyaniline polymer a mixture of a polythipophene polymer and a polymeric acid dopant.

28. The polymer composition of claim 27, wherein the polythiopene polymer comprises two or more monomeric units according to structure (I.a) per molecule of the polymer: 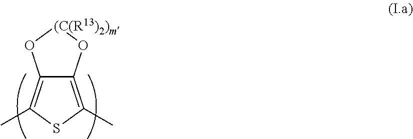
wherein:
each occurrence of R¹³ is independently H, alkyl, hydroxy, heteroalkyl, alkenyl, heteroalkenyl, hydroxalkyl, amidosulfonate, benzyl, carboxylate, ether, ether carboxylate, ether sulfonate, ester sulfonate, or urethane, and
m′ is 2 or 3.
and the polymeric acid dopant comprises poly((styrene sulfonate).

29. The polymer composition of claim 26, wherein the anisotropic electrically conductive nanostructures comprise silver nanowires have an average diameter of from about 10 to about 150 nm and an average length of from about 5 to about 150 μm.

30. The polymer composition of claim 26, wherein the silver nanowires have a average diameter of from 5 nm to 60 nm and an average aspect ratio of greater than 100.

31. The polymer composition of claim 26, wherein composition comprises, based on 100 parts by weigh of the silver nanowires, less than 1 part by weight of vinylpyrrolidone polymer.

32. The polymer composition of claim 26, wherein the anisotropic electrically conductive nanostructures comprise carbon nanofibers.

33. A method for making polymer film, comprising:
(1) forming a layer of a polymer composition, said polymer composition comprising
(a) a liquid carrier,
(b) one or more electrically conductive polymers dissolved or dispersed in the liquid carrier, and
(c) anisotropic electrically conductive nanostructures dispersed in the liquid carrier, and
(2) removing the liquid carrier from the layer.

34. The method of claim 33, wherein the anisotropic electrically conductive nanostructures comprise silver nanowires.

35. The method of claim 33, wherein the anisotropic electrically conductive nanostructures comprise carbon nanofibers.

36. A polymer film made by the method of claim 33.

37. An electronic device, comprising:
(a) an anode or combined anode and buffer layer 101,
(b) a cathode layer 106,
(c) an electroactive layer 104, disposed between anode layer 101 and cathode layer 106,
(d) optionally, a buffer layer 102,
(e) optionally, a hole transport layer 105, and
(f) optionally, an electron injection layer 105,
wherein at least one of at least one of the anode or combined anode and buffer layer 101, the cathode layer 106, and, if present, buffer layer 102 comprises a polymer film according to claim 12.

38. An electronic device, comprising:
(a) an anode or combined anode and buffer layer 101,
(b) a cathode layer 106,
(c) an electroactive layer 104, disposed between anode layer 101 and cathode layer 106,
(d) optionally, a buffer layer 102,
(e) optionally, a hole transport layer 105, and
(f) optionally, an electron injection layer 105,
wherein at least one of at least one of the anode or combined anode and buffer layer 101, the cathode layer 106, and, if present, buffer layer 102 comprises a polymer film made according to claim 31.
